(19) United States
(12) Patent Application Publication
(10) Pub. No.: US 2026/0247737 A1
(43) Pub. Date: Aug. 20, 2026

(54) TECHNOLOGIES FOR MICRO-LED OPTICAL INTERCONNECTS

(71) Applicants: Khaled Ahmed, San Jose, CA (US); Joshua B. Fryman, Corvallis, OR (US); Benjamin T. Duong, Phoenix, AZ (US)

(72) Inventors: Khaled Ahmed, San Jose, CA (US); Joshua B. Fryman, Corvallis, OR (US); Benjamin T. Duong, Phoenix, AZ (US)

(21) Appl. No.: 18/989,539

(22) Filed: Dec. 20, 2024

(51) Int. Cl. H10F 55/00; G02B 6/43; H10F 30/24; H10F 39/00; H10F 39/18

(52) U.S. Cl. CPC H10F 55/00; G02B 6/43; H10F 30/245; H10F 39/014; H10F 39/18; H10F 39/806; H10F 39/8053

(57) ABSTRACT

Technologies for micro-LED optical interconnects are disclosed. In an illustrative embodiment, micro-LEDs are used to drive optical signals coupled to a multi-mode fiber. The multi-mode fiber carries the light to a photodetector array. The photodetector array includes several pixels, each of which has several nanowire phototransistors. The nanowire phototransistors have a fast response time and a combined high quantum efficiency. The nanowire phototransistors may be wavelength selective, allowing for wavelength division multiplexing. Additionally or alternatively, a metasurface nanostructure may be included at the top and bottom of a photodetector, such as a photodiode or phototransistor, to filter out some wavelengths of light and increase detection of other wavelengths of light.

### BACKGROUND

As computing power increases, the bandwidth requirement likewise increases for communication over short distances, such as for communication between dies on the same circuit board or between circuit boards near each other. Copper traces and other electrical conductors are commonly used to carry high-bandwidth signals, but as frequencies increase, copper traces have more loss. In some cases, the loss for high-frequency signals can be significant even for dies adjacent to each other on the same circuit board.

### BRIEF DESCRIPTION OF THE DRAWINGS

FIG. 1 is an isometric view of a system with two integrated circuit components with micro-LED assemblies connected by an optical cable.

FIG. 2 is a cross-sectional view of one embodiment of one of the integrated circuit components of FIG. 1.

FIG. 3 is a cross-sectional view of one embodiment of a photodetector array of the integrated circuit components of FIG. 1.

FIG. 4 is a cross-sectional view of one embodiment of an optical fiber and a photodetector array of the integrated circuit components of FIG. 1.

FIG. 5 is a perspective view of one embodiment of a pixel of the photodetector array of FIG. 3.

FIG. 6 is a cross-sectional view of one embodiment of the pixel of the photodetector array of FIG. 5.

FIG. 7 is a cross-sectional view of one embodiment of the pixel of the photodetector array of FIG. 5.

FIG. 8 is a simplified flow diagram of at least one embodiment of a method for manufacturing an integrated circuit die with a photodetector array.

FIG. 9 is a cross-sectional view of one embodiment of an integrated circuit component at one stage of the flowchart of FIG. 8.

FIG. 10 is a cross-sectional view of one embodiment of an integrated circuit component at one stage of the flowchart of FIG. 8.

FIG. 11 is a cross-sectional view of one embodiment of an integrated circuit component at one stage of the flowchart of FIG. 8.

FIG. 12 is a cross-sectional view of one embodiment of an integrated circuit component at one stage of the flowchart of FIG. 8.

FIG. 13 is a cross-sectional view of one embodiment of an integrated circuit component at one stage of the flowchart of FIG. 8.

FIG. 14 is a cross-sectional view of one embodiment of an integrated circuit component at one stage of the flowchart of FIG. 8.

FIG. 15 is a cross-sectional view of one embodiment of an integrated circuit component at one stage of the flowchart of FIG. 8.

FIG. 16 is a cross-sectional view of one embodiment of an integrated circuit component at one stage of the flowchart of FIG. 8.

FIG. 17 is a cross-sectional view of one embodiment of an integrated circuit component at one stage of the flowchart of FIG. 8.

FIG. 18 is a cross-sectional view of one embodiment of an integrated circuit component at one stage of the flowchart of FIG. 8.

FIG. 19 is a cross-sectional view of one embodiment of an integrated circuit component at one stage of the flowchart of FIG. 8.

FIG. 20 is a cross-sectional view of one embodiment of an integrated circuit component at one stage of the flowchart of FIG. 8.

FIG. 21 is a cross-sectional view of one embodiment of one of the integrated circuit components of FIG. 1.

FIG. 22 is a simplified block diagram of one embodiment of a tile-based circuit.

FIG. 23 is a simplified block diagram of one embodiment of a tile FIG. 22.

FIG. 24 is a cross-sectional view of one embodiment of a photodiode with a metasurface filter.

FIG. 25 is a cross-sectional view of one embodiment of a phototransistor with a metasurface filter.

FIG. 26 is a top view of a wafer and dies that may be included in a microelectronic assembly in accordance with any of the embodiments disclosed herein.

FIG. 27 is a cross-sectional side view of an integrated circuit device that may be included in any of the microelectronic assemblies disclosed herein.

FIGS. 28A-28D are perspective views of example planar, FinFET, gate-all-around, and stacked gate-all-around transistors.

FIG. 29 is a cross-sectional side view of an integrated circuit device assembly that may include a microelectronic assembly in accordance with any of the embodiments disclosed herein.

FIG. 30 is a block diagram of an example electrical device that may include a microelectronic assembly in accordance with any of the embodiments disclosed herein.

### DETAILED DESCRIPTION

In various embodiments disclosed herein, an integrated circuit component includes a semiconductor die with an array of photodetectors and an array of micro-light-emitting diodes. In one embodiment, the array of photodetectors includes several pixels, and each pixel includes several floating base nanowire phototransistors. The phototransistors can provide gain, allowing for a high amperes/Watt ratio. The phototransistors for individual pixels have a shared emitter electrode and a shared collector electrode. The nanowire phototransistors provide a fast response due to low capacitance, while the high number of nanowire phototransistors with shared electrodes provide a higher efficiency. The nanowire phototransistors can act as a photonic crystal, establishing an acceptance angle and reducing cross-talk from adjacent pixels.

In some embodiments, the array of photodetectors includes pixels that are sensitive to different wavelengths, allowing for higher data rates using wavelength-division multiplexing. The individual pixels may be made sensitive to different wavelengths in any suitable manner, such as by filters at the top and/or bottom of the nanowires. In some embodiments, the filters may be formed by metasurfaces. The filters may create a resonant cavity, increasing the detection efficiency of the phototransistors. In some embodiments, photodiodes with metasurface filters may be used.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner.

“Connected” may indicate elements are in direct physical or electrical contact with each other and “coupled” may indicate elements cooperate or interact with each other, but they may or may not be in direct physical or electrical contact. Furthermore, the terms “comprising,” “including,” “having,” and the like, as used with respect to embodiments of the present disclosure, are synonymous.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components. As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y. As used herein, the phrase “electrically coupled” refers to the presence of one or more electrically conductive paths between components that are recited as being electrically coupled.

Certain terminology may also be used herein for the purpose of reference only, and thus are not intended to be limiting. For example, terms such as “upper,” “lower,” “above,” “below,” “bottom,” and “top” refer to directions in the Figures to which reference is made. Terms such as “front,” “back,” “rear,” and “side” describe the orientation and/or location of layers, components, portions of components, etc., within a consistent but arbitrary frame of reference, which is made clear by reference to the text and the associated Figures describing the layers, component, portions of components, etc. under discussion. Such terminology may include the words specifically mentioned above, derivatives thereof, and words of similar import.

As used herein, the term “integrated circuit component” refers to a packaged or unpacked integrated circuit product. A packaged integrated circuit component comprises one or more integrated circuit dies mounted on a package substrate with the integrated circuit dies and package substrate encapsulated in a casing material, such as metal, plastic, glass, or ceramic. In one example, a packaged integrated circuit component contains one or more processor units mounted on a substrate with an exterior surface of the substrate comprising a solder ball grid array (BGA). In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any computing system component described or referenced herein or any other computing system component, such as a processor unit (e.g., system-on-a-chip (SoC), processor core, graphics processor unit (GPU), accelerator, chipset processor), I/O controller, memory, or network interface controller.

As used herein, the term “electronic component” can refer to an active electronic component (e.g., processing unit, memory, storage device, transistor) or a passive electronic component (e.g., resistor, inductor, capacitor).

As used herein, the terms “operating,” “executing,” or “running” as they pertain to software or firmware in relation to a system, device, platform, or resource are used interchangeably and can refer to software or firmware stored in one or more computer-readable storage media accessible by the system, device, platform or resource, even though the software or firmware instructions are not actively being executed by the system, device, platform, or resource.

Reference is now made to the drawings, which are not necessarily drawn to scale, wherein similar or the same numbers may be used to designate the same or similar parts in different figures. The use of similar or the same numbers in different figures does not mean all figures including similar or the same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

As used in this application and the claims, a list of items joined by the term “and/or” can mean any combination of the listed items. For example, the phrase “A, B, and/or C” can mean A; B; C; A and B; A and C; B and C; or A, B and C. As used in this application and the claims, a list of items joined by the term “at least one of” can mean any combination of the listed terms. For example, the phrase “at least one of A, B, or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B, and C” can mean A; B; C; A and B; A and C; B and C; or A, B, and C.

As used in this application and the claims, the phrase “individual of” or “respective of” followed by a list of items recited or stated as having a trait, feature, etc., means that all of the items in the list possess the stated or recited trait, feature, etc. For example, the phrase “individual of A, B, or C, comprise a sidewall” or “respective of A, B, or C, comprise a sidewall” means that A comprises a sidewall, B comprises a sidewall, and C comprises a sidewall.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

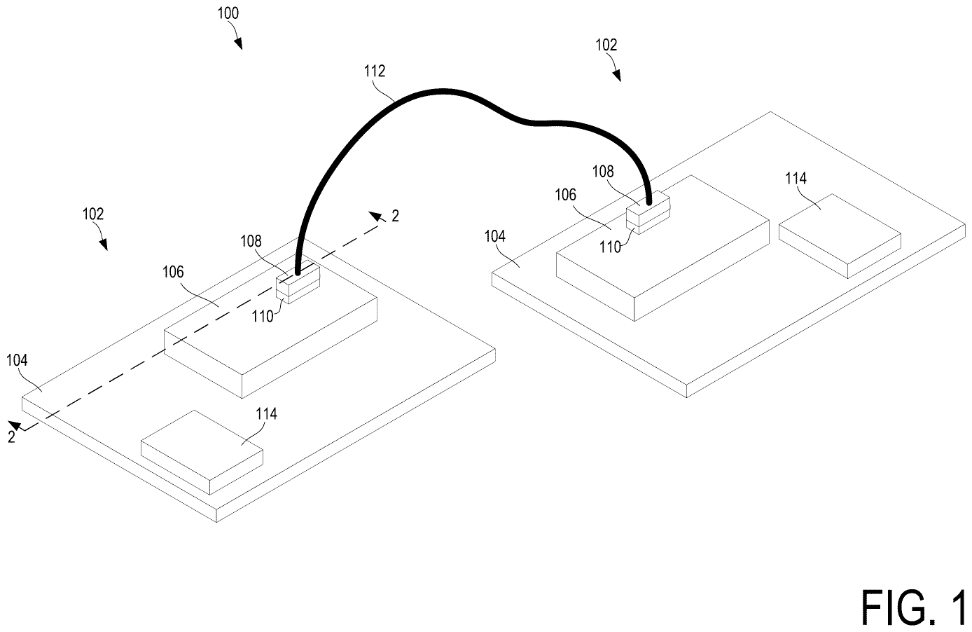

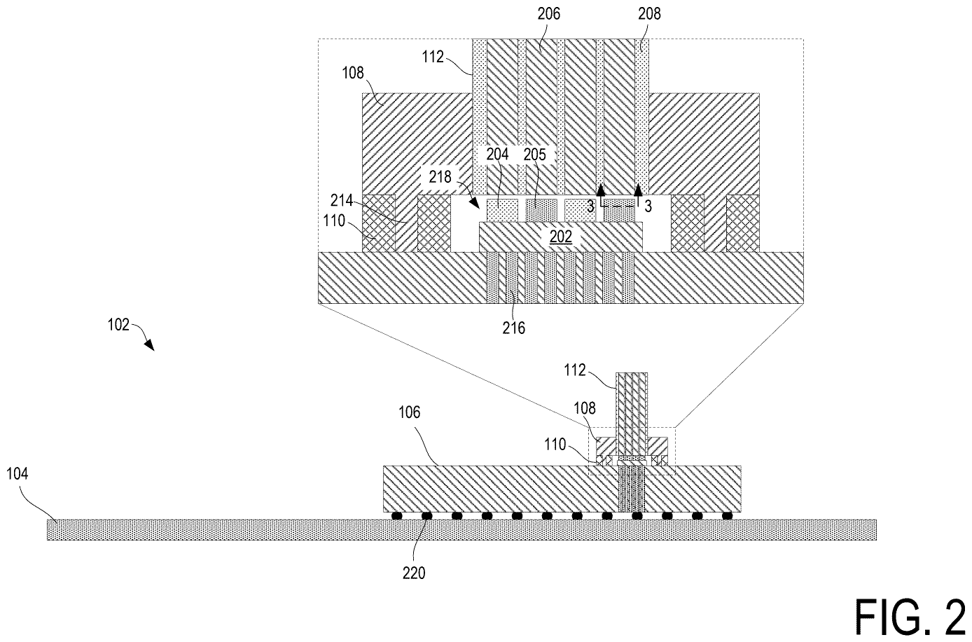

Referring now to FIGS. 1 and 2, in one embodiment, a system 100 includes two integrated circuit components 102. Each integrated circuit component 102 includes a circuit board 104 and an integrated circuit (IC) die 106. The integrated circuit components 102 are connected by an optical cable 112. FIG. 1 shows a perspective view of an integrated circuit component 102, and FIG. 2 shows a cross-sectional view of one embodiment of the integrated circuit component 102.

In an illustrative embodiment, a micro-LED assembly 218 is mounted on the back side of the IC die 106 (see FIG. 2). Circuitry, such as transistors, capacitors, resistors, etc., are on the front side of the die 106, facing the circuit board 104. The micro-LED assembly 218 mounted on the back side IC die 106 is connected to the front side of the IC die 106 by through-silicon vias 216. In an illustrative embodiment, the micro-LED assembly 218 includes a base die 202, one or more micro-LED arrays 204, and one or more photodetector arrays 205. Optical fiber cores 206 of the optical cable 112 are aligned with the micro-LED arrays 204 and/or the photodetector arrays 205. The optical fiber cores 206 are surrounded by a cladding 208 material. The optical cable 112 is attached to a plug 108, which is mated with a receptacle 110 mounted on the die 106. In the illustrative embodiment, the optical cable 112 includes a single multi-core fiber. Additionally or alternatively, the optical cable 112 may include several single-core fibers and/or several multi-core fibers, all of which may terminate at the plug 108.

In use, the micro-LED assembly 218 is connected to transistors, micro-LED driver circuitry, photodetector driver circuitry, etc., on the front side of the IC die 106 through the through-silicon vias 216. High-speed input/output (HSIO) data signals can be sent from the circuitry on the front side of the IC die 106 to and from the micro-LED assembly 218 with relatively high frequency and relatively low loss, such as sending signals at a frequency up to 1-32 gigahertz with a loss of less than 0.1-10 dB. In an illustrative embodiment, signals are sent to and received from the micro-LED assembly 218 at a frequency up to about 32 gigahertz with a loss of less than 3 dB. Electrical signals sent from the circuitry on the front side of the IC die 106 are converted by a micro-LED array 204 to an optical signal, which is coupled to the optical fiber core 206 in the optical cable 112. The optical signal is transported to another component, such as to the micro-LED assembly 218 on the other integrated circuit component 102. The optical signal is converted to an electrical signal at a photodetector array 205, and the electrical signal is sent to the circuitry on the front side of the IC die 106. In this manner, HSIO signals can be sent between the IC dies 106 with relatively low loss. The integrated circuit components 102 may be any suitable distance apart, such as 0.05-1,000 meters. The integrated circuit components 102 may be in the package, in the same housing, on the same printed circuit board, in the same rack, on the same blade, in the same data center, etc. In some embodiments, as described in more detail below, the optical cable 112 can connect micro-LED assemblies 218 on two different dies 106 on the same circuit board 104.

The illustrative circuit board 104 may be made from ceramic, glass, and/or organic-based materials with fiberglass and resin, such as FR-4. The circuit board 104 may have any suitable length or width, such as 10-500 millimeters. The circuit board 104 may have any suitable thickness, such as 0.2-5 millimeters. The circuit board 104 may support additional components besides the components shown in FIG. 1 or 2, such as additional photonic or electronic integrated circuit components, a memory device, additional circuit components, etc.

The circuit board 104 may have an organic or inorganic core, such as an organic core of resin and fiberglass or an inorganic core, such as a glass core. A glass core may be made of any suitable material that may be crystalline, non-crystalline, amorphous, etc., such as fused silicon, borosilicate, sapphire, yttrium aluminum garnet, etc. The glass core may be, e.g., aluminosilicate glass, borosilicate glass, alumino-borosilicate glass, silica, fused silica. The glass core may include one or more additives, such as Al2O3, B2O3, MgO, CaO, SrO, BaO, SnO2, Na2O, K2O, SrO, P2O3, ZrO2, Li2O, Ti, and Zn. The glass core may comprise silicon and oxygen, as well as any one or more of aluminum, boron, magnesium, calcium, barium, tin, sodium, potassium, strontium, phosphorus, zirconium, lithium, titanium, and zinc. The glass core may include at least 20-40 percent silicon by weight, at least 20-40 percent oxygen by weight, and at least 5 percent aluminum by weight. For example, some embodiments of the glass core may include, e.g., at least 20-23 percent silicon and at least 20-26 percent oxygen by weight.

The one or more IC dies 106 may include any suitable electronic integrated circuit component, such as resistors, capacitors, inductors, transistors, etc. The one or more IC dies 106 may include any suitable analog and/or digital circuitry, such as a processor, a memory, an application-specific integrated circuit (ASIC), a field-programmable gate array (FPGA), a router, a network switch, a modem, communication circuitry, a motherboard, a daughterboard, a mezzanine board, an auxiliary board, etc. The IC dies 106 may have any suitable length or width, such as 1-300 millimeters. The IC dies 106 may have any suitable thickness, such as 0.05-5 millimeters. The through-silicon vias 216 may extend through any suitable height, such as through the entire IC die 106. The through-silicon vias 216 may be filled with any suitable conductive material, such as copper, tungsten, conductive polymers, polysilicon, and/or the like. In some embodiments, the through-silicon vias 216 may extend from, e.g., the back side of the IC die 106 to transistors on the front end-of-line (FEOL) portion of the front side of the IC die 106.

The integrated circuit component 102 may include other components, such as additional IC dies 114, components such as capacitors, inductors, voltage regulators, etc. In an illustrative embodiment, the IC die 106 is connected to the circuit board 104 with solder balls 220.

The optical cable 112 may include any suitable number of optical fiber cores 206, such as 1-10,000. In an illustrative embodiment, the optical cable 112 includes an optical fiber core 206 for each micro-LED array 204 and each photodetector array 205. The optical fiber cores 206 may be any suitable material that is transparent to the wavelength used, such as glass, fused silica, plastic, etc. In an illustrative embodiment, the optical fiber cores 206 are multi-mode fibers with a core diameter of, e.g., 50-100 micrometers. In other embodiments, the optical fiber cores 206 may be single- or few-mode fibers with a core diameter of, e.g., 1-10 micrometers. In some embodiments, the optical fiber cores 206 may be part of polarization-maintaining optical fibers. The cladding 208 may be any suitable material with a lower index of refraction than the core 206, such as glass, fused silica, or plastic. The optical fiber cores 206 may have a different doping than the cladding 208 in order to change the difference in index of refraction between the core 206 and the cladding 208. The optical cable 112 may have any suitable length, such as 0.1-1,000 meters. In some embodiments, a microlens array (or pair of micro lens arrays) may be positioned between the micro-LED arrays 204/photodetector arrays 205 and the optical fiber cores 206 in order to increase coupling to and from the optical fiber cores 206.

The optical cable 112 terminates at an optical plug 108. The optical plug 108 includes a housing that holds the end of the optical cable 112 in place. The housing of the optical plug 108 may be any suitable material, such as plastic, ceramic, metal, glass, a combination thereof, etc. The optical plug 108 mates with an optical receptacle 110 mounted on the surface of the die 106. The optical receptacle 110 may be made of any suitable material, such as plastic, ceramic, metal, glass, a combination thereof, etc. In an illustrative embodiment, an alignment feature 214 extends from the optical plug 108 and mates with a corresponding alignment feature defined in the optical receptacle 110. The optical receptacle 110 may be attached to the die 106 in any suitable manner, such as by using die bonding films, epoxy adhesives, bump bonding, hybrid bonding, etc. The optical plug 108 and/or the optical receptacle 110 may include additional components for aligning and/or retaining the optical plug 108, such as alignment grooves, clips, tabs, etc. In use, the optical plug 108 can be removably plugged into the optical receptacle 110. In doing so, the optical cable 112 is positioned to couple light from the micro-LED arrays 204 to the optical fiber cores 206 and/or light from the optical fiber cores 206 into the photodetector arrays 205. The optical plug 108 can be plugged and unplugged into various components as necessary as a system is set up, taken apart, reconfigured, etc.

In the illustrative embodiment, each micro-LED array 204 has a corresponding photodetector array 205 next to it on the same die 202, creating one or more transmit/receive pairs. In other embodiments, a die 202 may have more receive channels or more transmit channels. Each micro-LED array 204 and photodetector array 205 is connected to a drive and receive circuit, respectively, that interfaces with other electronic components of the base die 202 and/or IC die 106. The micro-LED assembly 218 may include any suitable number of micro-LED arrays 204 and/or photodetector arrays 205, such as 1-10,000. Each micro-LED array 204 may transmit, and each photodetector array 205 may receive data at a rate of, e.g., 1-128 gigabits per second per wavelength channel. In the illustrative embodiment, the IC die 106 sends data by modulating the micro-LED array 204 at different amplitudes, such as on and off. Any suitable encoding may be used, such as return-to-zero encoding, non-return-to-zero encoding, amplitude shift keying, multilevel amplitude shift keying, pulse amplitude modulation, phase shift keying, quadrature amplitude modulation, etc. In the illustrative embodiment, data can be transferred by a micro-LED array 204 to a photodetector array 205 with an energy efficiency of less than 0.5 picojoules per bit over a range of up to, e.g., 1-50 meters. In other embodiments, data can be transferred by a micro-LED array 204 to a photodetector array 205 with an energy efficiency of, e.g., less than 0.05-5 picojoules per bit. Each micro-LED array 204 and/or photodetector array 205 may include any suitable number of wavelength channels, such as 1-1,024.

In one embodiment, each micro-LED assembly 218 includes the micro-LED arrays 204 and photodetector arrays 205 in a linear array, as shown in FIG. 2. In other embodiments, each micro-LED assembly 218 may array the micro-LED arrays 204 and photodetector arrays 205 in a two-dimensional array, such as an array with a length and/or width of 1-1,000 micro-LED arrays 204 or photodetector arrays 205. In some embodiments, the micro-LED arrays 204 and photodetector arrays 205 may be alternating, as shown in the figures. In other embodiments, micro-LED arrays 204 may be grouped together (e.g., in a line or a two-dimensional array), and photodetector arrays 205 may be grouped together (e.g., in a line or a two-dimensional array).

In the illustrative embodiment, the photodetector arrays 205 are spaced apart from other photodetector arrays 205 and/or from micro-LED arrays 204 in order to prevent cross-talk. The photodetector arrays 205 and/or micro-LED arrays 204 may be spaced apart by, e.g., 10-500 micrometers, as measured from the center of one photodetector array 205 and/or micro-LED array 204 to the next.

In an illustrative embodiment, the micro-LED assembly 218 includes a base die 202, one or more micro-LED arrays 204, and one or more photodetector arrays 205. The base die 202 may be a silicon semiconductor die. In other embodiments, the base die 202 may be another type of die, such as glass, a III-V semiconductor die composing, e.g., boron, aluminum, gallium, indium, nitrogen, phosphorus, arsenic, tin, etc. The base die 202 may include one or more through-silicon (or through-substrate) vias, traces, pads, etc. The base die 202 may include one or more layers of traces. In an illustrative embodiment, driver circuitry for the micro-LED arrays 204 and/or the photodetector arrays 205 are on the front side of the IC die 106. In some embodiments, the base die 202 may include driver circuitry for the micro-LED arrays 204 and/or the photodetector arrays 205.

The micro-LED arrays 204 may include any suitable micro-LED, such as gallium nitride micro-LEDs, quantum dot LEDs, single nanowire LED, single nanopyramid LED, an array of nanowire LEDs connected in parallel, an array of nanopyramid LEDs connected in parallel, etc. As used herein, a micro-LED refers to a light-emitting diode with a length and width of a light-emitting surface of less than 100 micrometers. In some embodiments, the length and/or width of a light-emitting surface of the micro-LEDs of the micro-LED arrays 204 may be smaller, such as less than 1-50 micrometers. In the illustrative embodiment, the micro-LEDs of the micro-LED arrays 204 are created on a separate substrate and transferred to the base die 202, the IC die 106, or other dies.

The micro-LEDs of the micro-LED array 204 may have any suitable wavelength, such as 380-1,500 nanometers, depending on the particular material and structure of the micro-LEDs of the micro-LED array 204. In the illustrative embodiment, the micro-LEDs of the micro-LED arrays 204 may have a wavelength between, e.g., 400-450 nanometers. The micro-LEDs of the micro-LED arrays 204 may have any suitable emission linewidth, such as 1-15 nanometers.

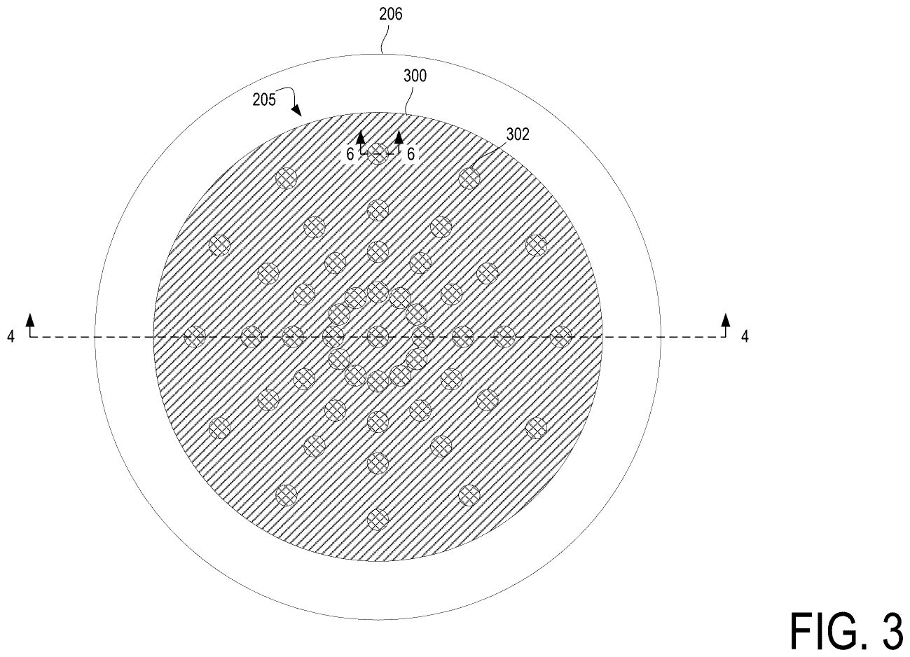

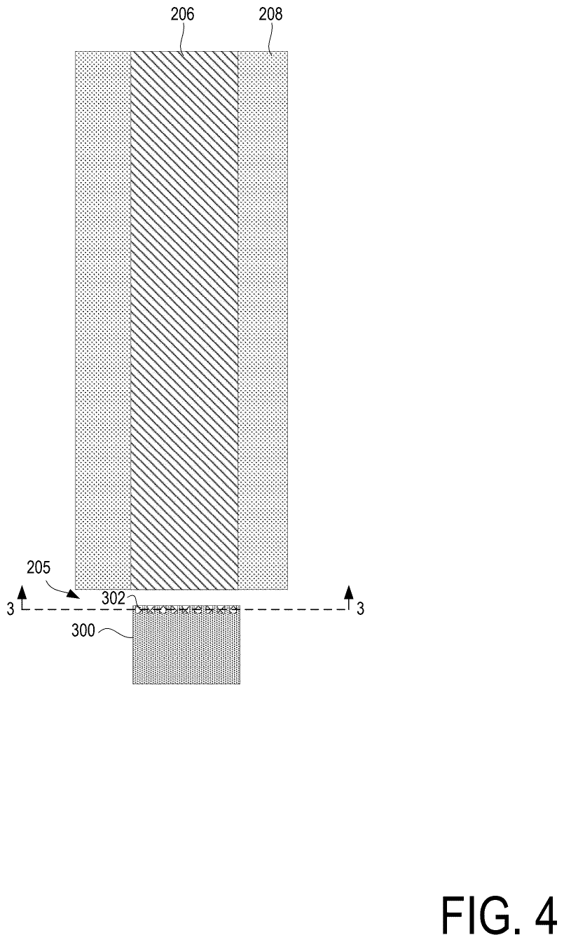

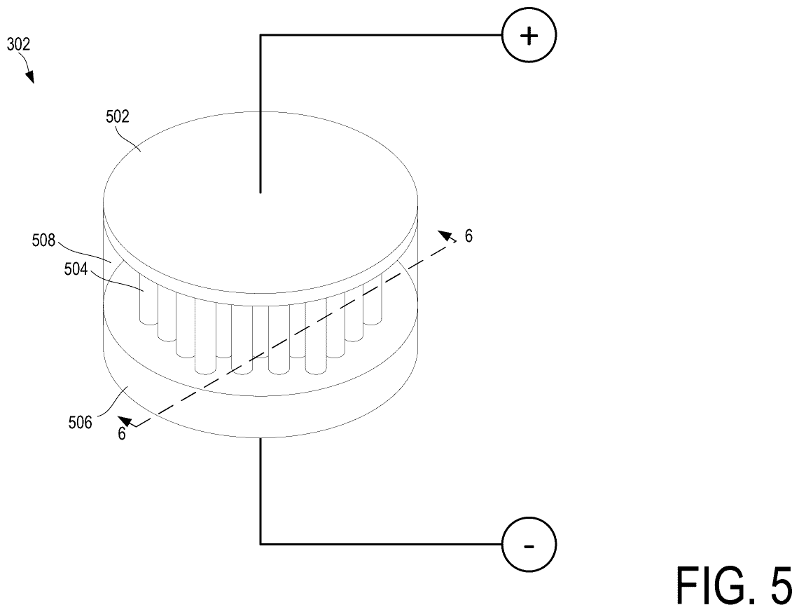

Referring now to FIGS. 3 and 4, in an illustrative embodiment, a zoomed-in view of a photodetector array 205 is shown. FIG. 3 shows a cross-sectional bottom-up view, from the perspective of looking up at the optical fiber core 206. FIG. 4 shows a cross-sectional side view. As shown in the figure, the photodetector array 205 includes a substrate die 300 and several pixels 302 of the photodetector array 205. The pixels 302 are described below in more detail in regard to FIGS. 5-7. The substrate die 300 may be any suitable material, such as silicon.

In order to reduce the energy per bit consumption, the photodetector array 205 benefits from a high responsivity or high internal gain. Silicon photodiodes have responsivity that is limited by the quantum efficiency, with typical values of 0.1 amperes per Watt at the visible wavelengths emitted by micro-LEDs (e.g., 450 nm). For a target energy per bit consumption by the system approaching <0.5 pJ/bit, the responsivity of photodetector array 205 benefits from being closer to 1 ampere per Watt, ten times higher than what is offered by silicon CMOS photodetectors.

The photodetector array 205 may include any suitable number of pixels 302, such as 1-3,000. In an illustrative embodiment, different sets of pixels 302 of the photodetector array 205 may be sensitive to different wavelengths. As light in a given wavelength may generally be in any of multiple modes in the optical fiber core 206, the pixels 302 sensitive to a given wavelength may be spread around the photodetector array 205, so that at least some pixels 302 sensitive to a given wavelength may detect light from any mode supported by the optical fiber core 206. Each pixel 302 may have any suitable diameter, such as 0.5-10 micrometers. In an illustrative embodiment, each pixel 302 has a diameter of about 1 micrometer.

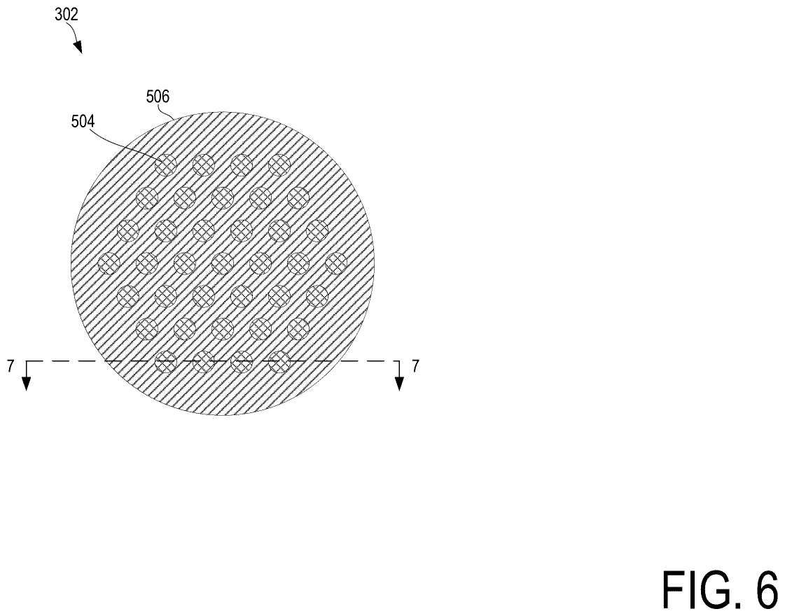

Referring now to FIGS. 5 and 6, in one embodiment, a pixel 302 of a photodetector array 205 includes several nanowire phototransistors 504, a transparent fill dielectric 508 between the nanowire phototransistors 504, an emitter electrode 502, and a collector electrode 506. FIG. 5 shows a perspective view of the pixel 302 and FIG. 6 shows a cross-sectional top-down view of the pixel 302. It should be appreciated that, in the illustrative embodiment, several nanowire phototransistors 504 are connected to the same emitter electrode 502 and collector electrode 506. As described in more detail below, the individual nanowire phototransistors 504 have a fast response due to low capacitance, and the multiple nanowire phototransistors 504 increase the detection efficiency without sacrificing the fast response.

In an illustrative embodiment, there is a voltage bias across the collector electrode 506 and the emitter electrode 502. For example, the collector electrode 506 may be connected to a negative voltage source, and the emitter electrode 502 may be connected to a positive voltage source. In the illustrative embodiment, the polarity of the bias is such that the collector-base junction is reverse biased, and the emitter-base junction is forward biased. In an illustrative embodiment, the array of nanowire phototransistors 504 form a photonic crystal, preventing propagation of certain wavelengths of light in certain directions. In some embodiments, the pitch and size of the nanowire phototransistors 504 will determine the detection wavelength due to the optical bandgap of the photonic crystal.

In an illustrative embodiment, the electrodes 502, 506 are transparent electrodes. The electrodes 502, 506 may be any suitable transparent conductive material, such as indium tin oxide (ITO). The transparent fill dielectric 508 may be any suitable transparent material, such as silicon dioxide, polymers such as polymethylmethacrylate (PMMA), silicon nitride, transparent epoxies, borophosphosilicate glass, and/or the like. In some embodiments, the fill dielectric 508 may not be transparent or may not be present.

In a multi-nanowire pixel, despite all phototransistors being connected in parallel at the two terminals, the base potential governing the current amplification is floating. As a result, the amplification in each individual nanowire phototransistor is carried out independently and thereby only governed by its own base capacitance. All the amplified photocurrents then add in parallel at the pixel terminals, so the total photo response current output of a pixel with N pillars to a step-like pulse of light with Nₚ photons per response time is expressed by:

$${I}_{ph} ( t ) = [ 1 - exp ( \frac{- t}{{r}_{d} {C}_{BE}} ) ] {\sum }_{i = I}^{N} {I}_{s} [ exp ( \frac{q {η}_{i} {N}_{ph} / {C}_{BE , i}}{{n}_{F} kT / q} ) - 1 ] ,$$

where r_{d} is the dynamic resistance, Iₛ is the saturation current, q is the fundamental charge, ηᵢ is the quantum efficiency of the ith nanowire, Nₚₕ is the number of photons, η_{F} is the ideality factor, k is the Boltzmann's constant, T is the temperature, and C_{BE,i} is the capacitance of each pillar. The capacitance term C_{BE,i}, governing the photoresponse of multipillar pixels, refers to the capacitance of each individual pillar and not to the overall capacitance between the pixel terminals. Since all individually amplified photocurrents add in parallel at the pixel terminals, the global pixel response time will be the average of the response times of the individual nanowire phototransistors.

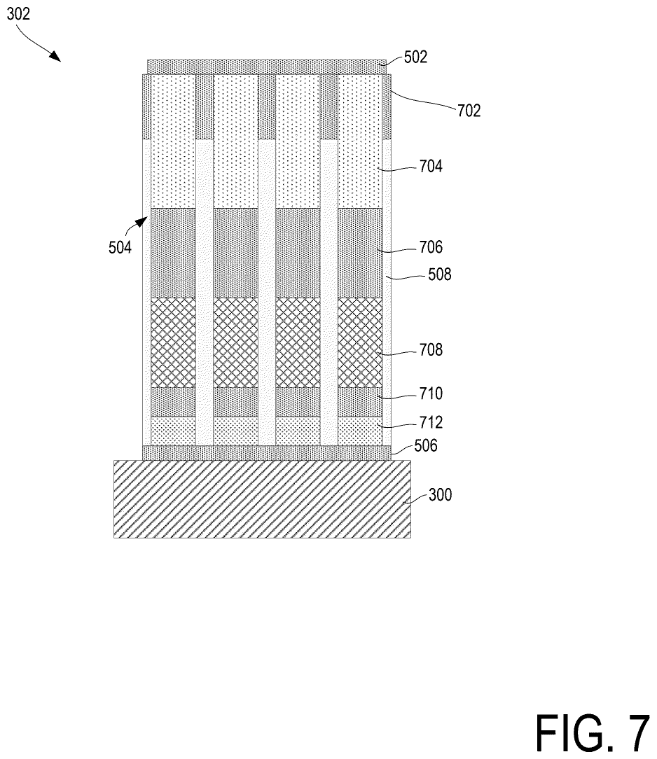

Referring now to FIG. 7, in one embodiment, cross-sectional view of a pixel 302 with several nanowire phototransistors 504 is shown. Each nanowire phototransistor 504 includes the emitter electrode 502, a sub-collector region 704, a collector region 706, a multi-quantum well region 708, a floating base region 710 (or floating gate region), an emitter region 712, and the emitter electrode 506. The various regions of a nanowire phototransistor 504 may include any suitable material or combination of materials that can function together as a phototransistor.

In an illustrative embodiment, the sub-collector region 704 is n-doped gallium nitride, the collector region 706 is n-doped indium gallium nitride, the multi-quantum well region 708 includes layers of indium gallium nitride and gallium nitride, the floating base region 710 is p-doped indium gallium nitride, and the emitter region 712 is n-doped gallium nitride. Of course, in other embodiments, other structures or materials may be used. In one embodiment, the emitter region 712 is gallium nitride, the floating base region 710 is InₓGa₁₋ₓN with x=0.05, the sub-collector region 704 is a multi-quantum well of InₓGa₁₋ₓN/GaN with x=0.2, and the collector region 706 is gallium nitride. In another embodiment, the emitter region 712 is silicon, the floating base region 710 is Si₁₋ₓGeₓ with x=0.05, the sub-collector region 704 is a multi-quantum well of Si₁₋ₓGeₓ/Si with x=0.1, and the collector region 706 is silicon. In some embodiments, a III-N system allows for bottom-up growth, and a silicon/silicon-germanium system can be done using a top-down approach.

In some embodiments, one or more filters may be disposed at the top and/or bottom of the nanowire phototransistor, such as above or below either or both of the electrodes 502, 506. The filters may be any suitable type of filter, such as an interference filter, a metasurface filter, and/or in the like. In some embodiments, the filters may form a resonant cavity, increasing absorption at a resonant wavelength, as described in more detail below. Additionally or alternatively, the filters may reject wavelengths outside of a target wavelength band.

In use, incoming photons are absorbed in the multi-quantum well region 708, creating free carriers. Some of the free carriers travel to the floating base region 710, where they can allow additional current to flow through the phototransistor 504. In this manner, the phototransistor 504 can have an electrical response of greater than one electron per photon, amplifying the signal compared to a photodiode, which is generally limited to one electron per photon. The current of the phototransistors 504 is combined at the electrodes 502, 506.

In an illustrative embodiment, the diameter of a nanowire phototransistor 504 may be, e.g., 200-300 nanometers. In other embodiments, a nanowire phototransistor 504 may have a different diameter, such as 50-1,000 nanometers. The nanowire phototransistor 504 may have any suitable thickness, such as 100-10,000 nanometers. In an illustrative embodiment, the collector region 706 has a thickness of 500-2,000 nanometers, the floating base region 710 has a thickness of 10-100 nanometers, the emitter region 712 has a thickness of 5-30 nanometers, and individual InₓGa₁₋ₓN quantum wells with x=0.2 may have a thickness of about 4 nanometers. In some embodiments, the indium fraction may be used to target a desired wavelength. The tuning of individual pixels to a specific wavelength enables wavelength demultiplexing with minimal to no use of optical elements, which lowers the cost of manufacturing. The multi-quantum well region 708 may have any suitable number of quantum wells, such as 1-100 quantum wells. In other embodiments, the various regions may be larger or smaller, depending on the particular design of the nanowire phototransistor 504.

In an illustrative embodiment, the high gain of the nanowire phototransistors 504 allows for using relatively small transimpedance amplifier circuitry at the receiver end, which enables the use of a larger TX/RX array per chip shoreline, leading to higher bandwidth per shoreline.

In an illustrative embodiment, the photodetector arrays 205 include an array of nanowire phototransistors 504, as described above in regard to FIGS. 3-7. In other embodiments, the photodetector arrays 205 may be a different type of photodetector, such as an axial nanowire with a p-i-n structure, with the intrinsic layer being a multi-quantum well. In some embodiments, a triangular barrier diode with gain may be used. In some embodiments, the photodetector arrays 205 may be similar to or the same as the micro-LED arrays 204, with an opposite bias to detect light rather than create it. The photodetector arrays 205 may be made from any suitable materials, such as silicon, silicon-germanium (SiGe), a III-V material including those listed above for the micro-LED arrays 204, etc. In some embodiments, the photodetector arrays 205 may include microphotodiodes. As used herein, a microphotodiode refers to a photodiode with a length and width of a light-sensitive surface of less than 100 micrometers. In some embodiments, the length and/or width of a light-sensitive surface of the microphotodiodes may be smaller, such as less than 10-50 micrometers. Similar to the micro-LEDs of the micro-LED arrays 204, the photodetector arrays 205 may be created on a separate substrate and transferred to the base die 202. In some embodiments, the microphotodiodes of the photodetector arrays 205 may be able to be used as micro-LEDs of a micro-LED array 204 and/or the micro-LEDs of the micro-LED array 204 may be able to be used as photodetectors of a photodetector array 205. In the illustrative embodiment, each micro-LED of the micro-LED arrays 204 and microphotodiodes of the photodiode arrays 205 interfaces with the die 202 on which they are mounted through a copper pad on the die 202 and a transparent electrode on top of the micro-LED or microphotodiode. The transparent electrode may be any suitable transparent conductive material, such as indium tin oxide (ITO). The micro-LEDs and/or photodetector arrays may be secured to the base die 202 in any suitable manner, such as by using solder, hybrid bonding, etc.

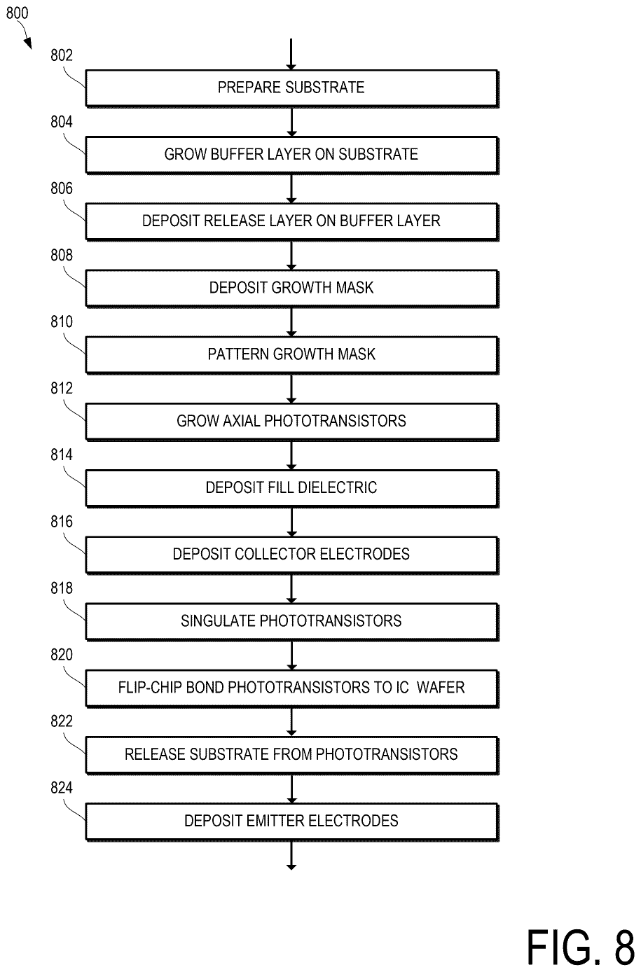

Referring now to FIG. 8, in one embodiment, a flowchart for a method 800 for creating the integrated circuit component 102 is shown. The method 800 may be executed by a technician and/or by one or more automated machines. In some embodiments, one or more machines may be programmed to do some or all of the steps of the method 800. Such a machine may include, e.g., a memory, a processor, data storage, etc. The memory and/or data storage may store instructions that, when executed by the machine, cause the machine to perform some or all of the steps of the method 800. The method 800 may use any suitable set of techniques that are used in semiconductor processing or circuit board processing, such as chemical vapor deposition, atomic layer deposition, physical layer deposition, molecular beam epitaxy, layer transfer, photolithography, ion implantation, dry etching, wet etching, selective laser etching, thermal treatments, flip chip, layer transfer, magnetron sputter deposition, pulsed laser deposition, laser machining, laser-induced deep etching, 3D photolithography, screen printing, ink jet printing, etc. It should be appreciated that the method 800 is merely one embodiment of a method to create one embodiment of a system and other methods may be used to create any suitable embodiment of the system. In some embodiments, steps of the method 800 may be performed in a different order than that shown in the flowchart.

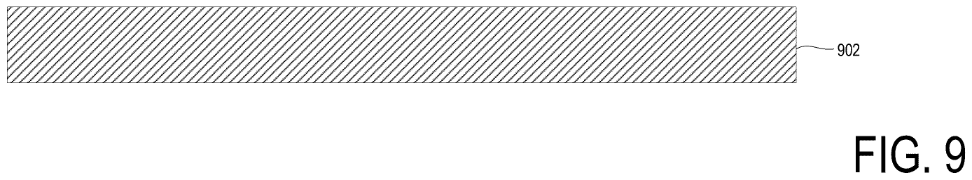

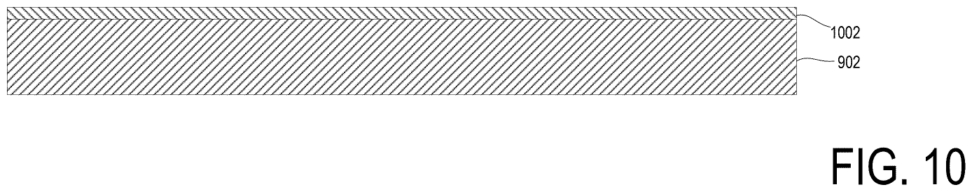

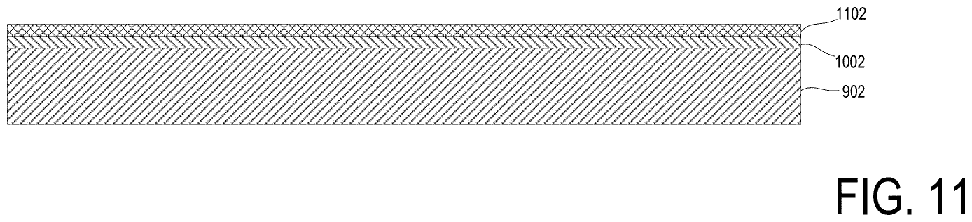

The method 800 begins in block 802, in which a substrate 902 is prepared, such as by dicing, polishing, etc., as shown in FIG. 9. The substrate 902 may be any suitable material, such as silicon, silicon carbine, sapphire, and/or the like. In block 804, a buffer layer 1002 is grown on the substrate 902, as shown in FIG. 10. The buffer layer 1002 may be any suitable material, such as gallium nitride, aluminum gallium nitride, and/or the like. A release layer 1102 is then deposited on the buffer layer 1002 in block 806, as shown in FIG. 11. The release layer 1102 may be any suitable material, such as silicon dioxide, silicon nitride, aluminum nitride, etc.

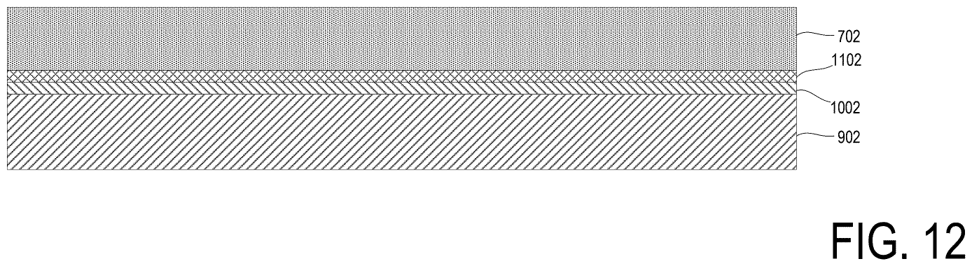

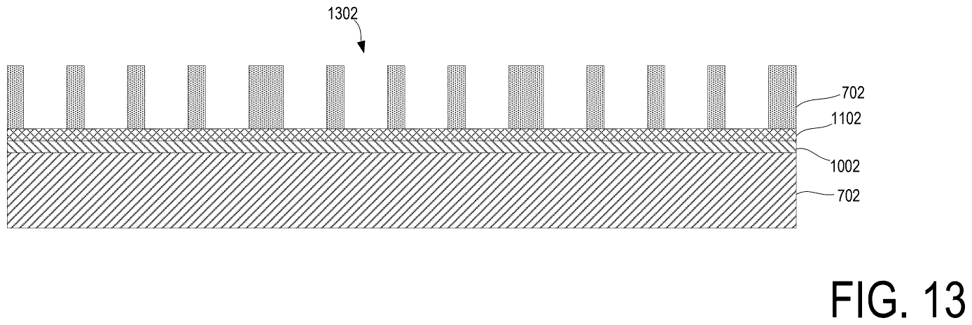

In block 808, a growth mask 702 is deposited on the release layer 1102, as shown in FIG. 12. The growth mask 702 may be any suitable material, such as silicon dioxide, silicon nitride, titanium, titanium nitride, nickel, aluminum oxide, magnesium oxide, and/or the like. In block 810, the growth mask 702 is patterned, as shown in FIG. 13, creating cavities 1302 in the growth mask 702.

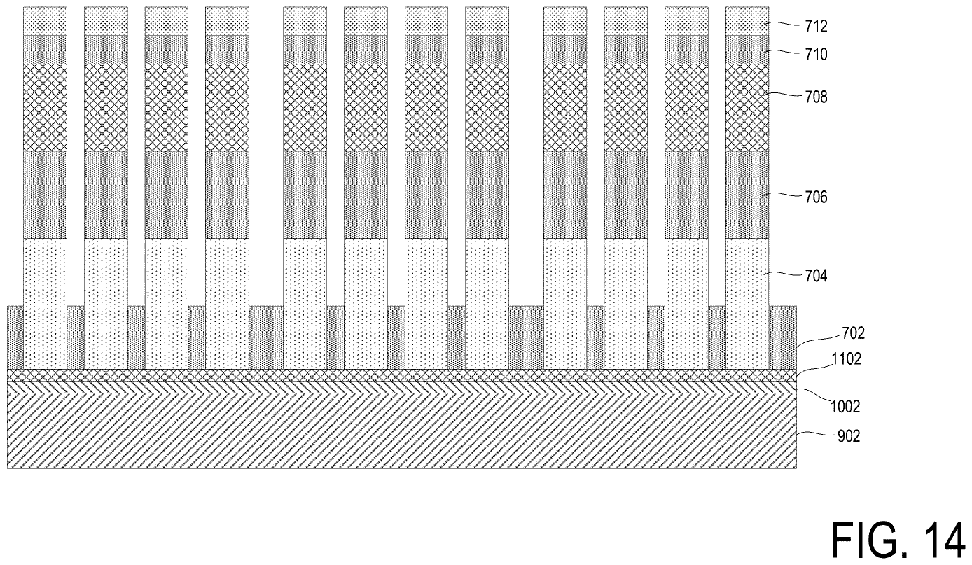

In block 812, the nanowire phototransistors are grown, as shown in FIG. 14. In an illustrative embodiment, the nanowire phototransistors may be grown using molecular beam epitaxy. In some embodiments, the nanowire phototransistors may be grown using metalorganic chemical vapor deposition. When growing n-type GaN emitter on p-type base, it is possible in a nanowire structure that hydrogen does not deactivate the p-type doping of the base layer during the growth of the n-type emitter on top of the base. The dimensions of the nanowire allow fast purge of hydrogen via the sides. Without this approach, such as for large planar phototransistors and/or for non-GaN material systems, this problem will prevent operation of the phototransistor due to deactivation of p-type dopants in the base during the growth of the n-type emitter.

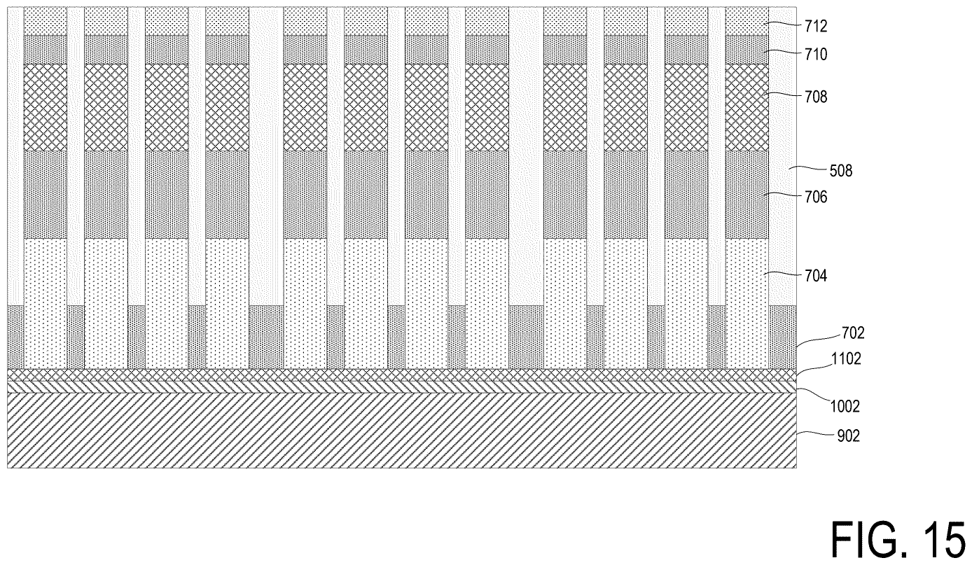

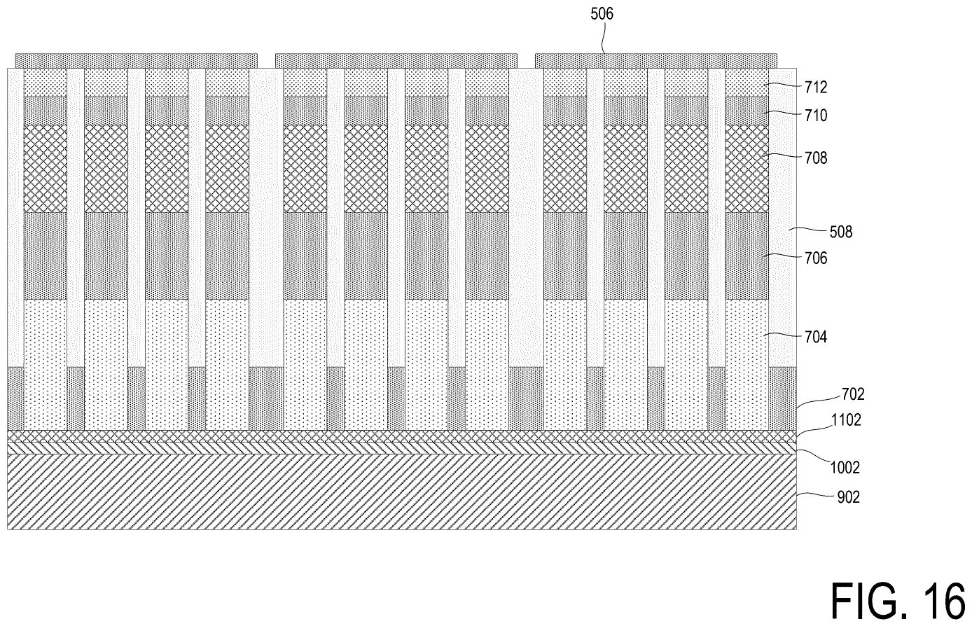

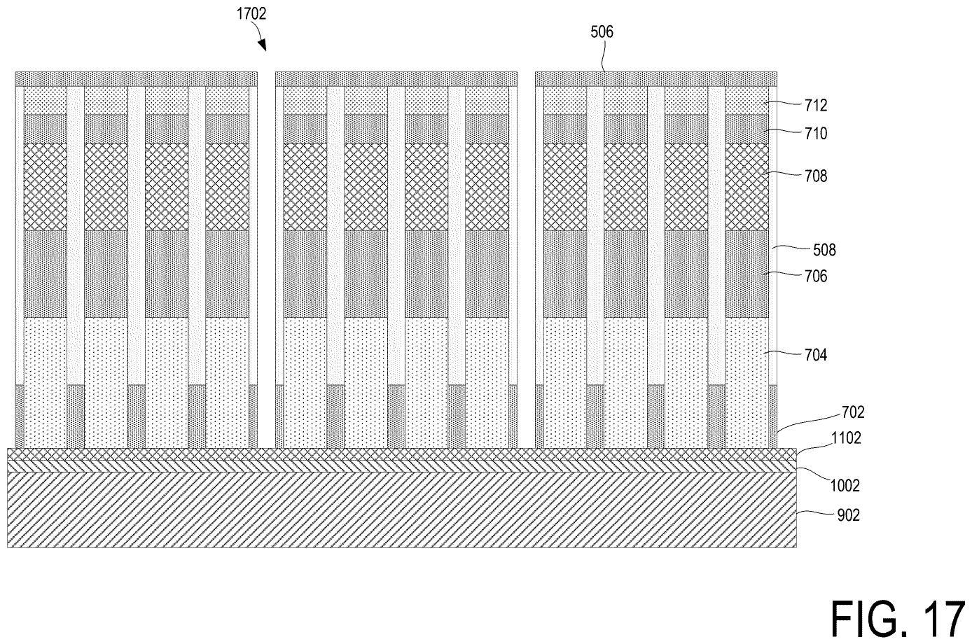

In block 814, a fill dielectric 508 is deposited, as shown in FIG. 15. In some embodiments, the fill dielectric 508 may act as a passivation layer. Additionally or alternatively, in some embodiments, there may be a separate passivation layer around the nanowire phototransistors. In block 816, collector electrodes 506 are deposited on the nanowire phototransistors and patterned, as shown in FIG. 16. In block 818, the nanowire phototransistors are singulated by etching gaps 1702 between them, as shown in FIG. 17

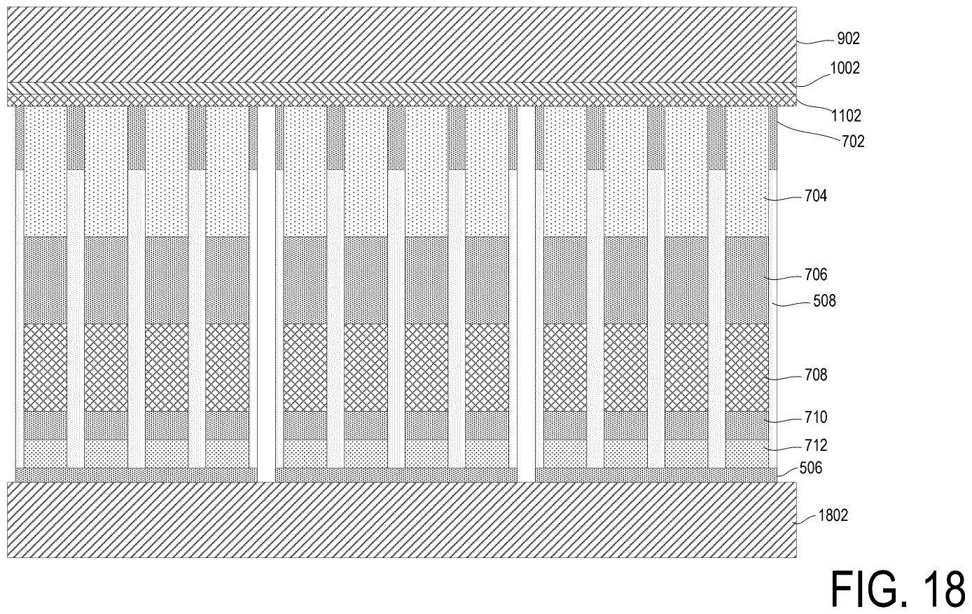

In block 820, the nanowire phototransistors are flip-chip bonded to an integrated circuit wafer 1802, as shown in FIG. 18. The wafer 1802 may be any suitable material, such as silicon. In some embodiments, the wafer 1802, after dicing, is the substrate die 300.

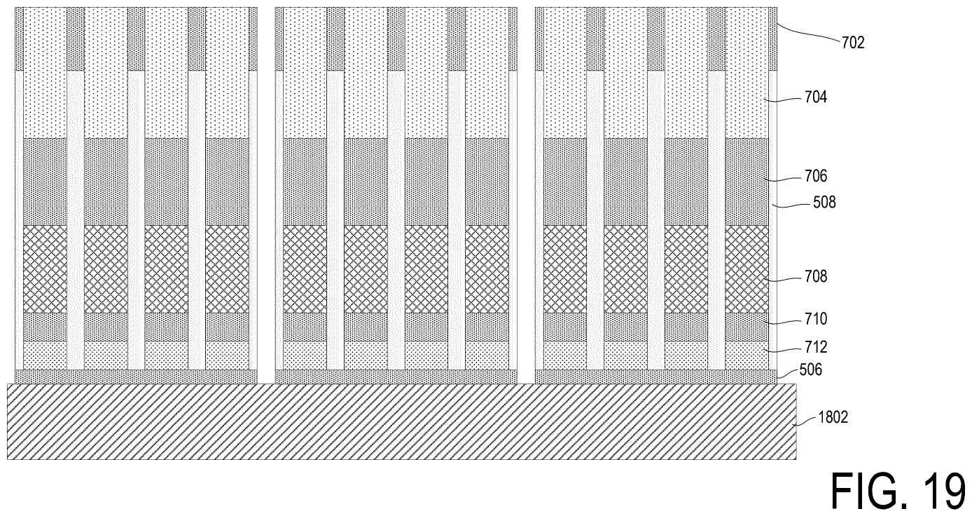

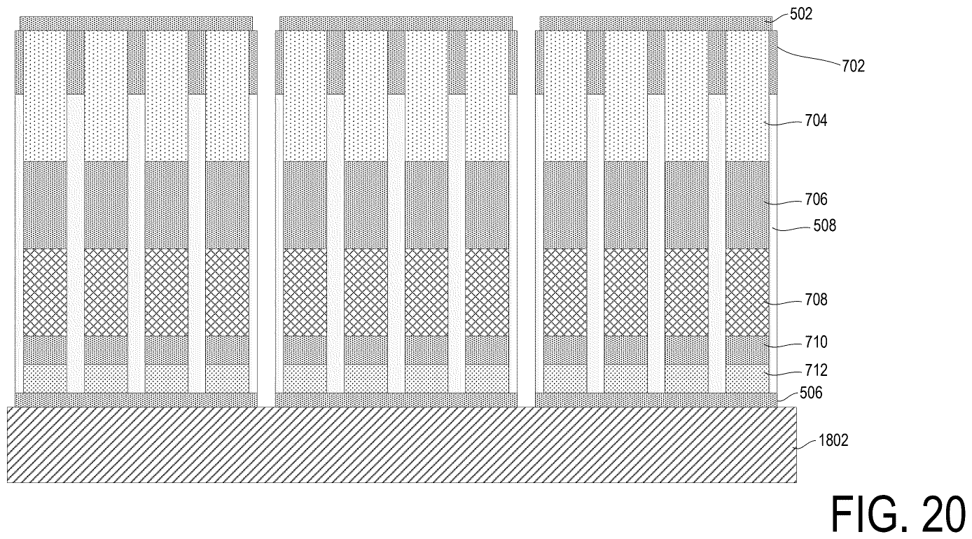

In block 822, the substrate 902 is released from the nanowire phototransistors, as shown in FIG. 19. In block 824, emitter electrodes 502 are deposited on the nanowire phototransistors, as shown in FIG. 20.

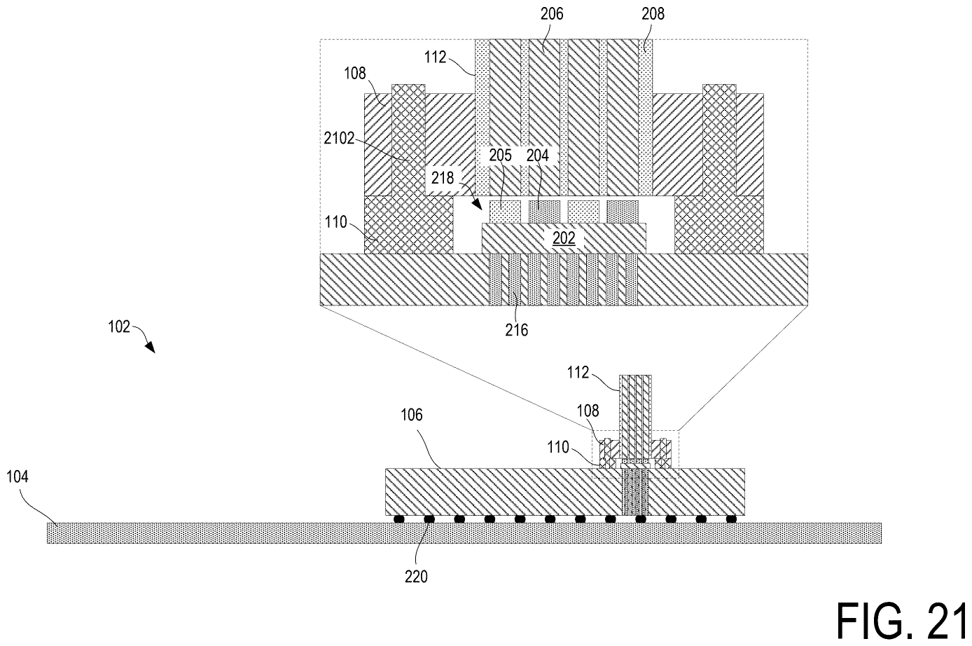

It should be appreciated that configurations besides those shown in FIGS. 1 and 2 are envisioned. For example, in some embodiments, the receptacle 110 includes alignment features 2102, rather than the plug 108, as shown in FIG. 21.

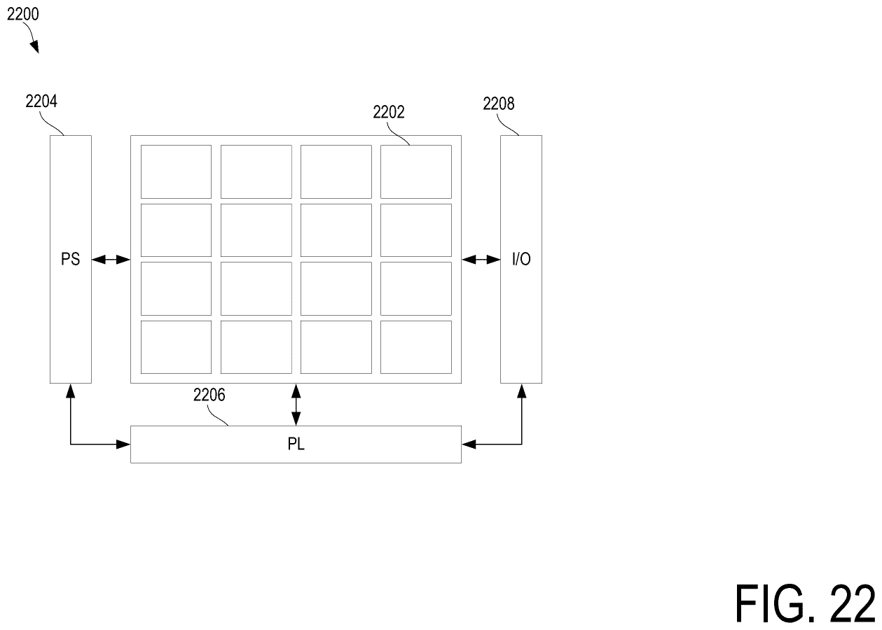

Referring now to FIG. 22, in one embodiment, a system 2200 for a tile-based compute engine, such as an artificial intelligence (AI) engine, includes one or more compute tiles 2202, a processor system 2204, programmable logic 2206, and input/output 2208. The various interconnects, such as between adjacent compute tiles 2202 and between the compute tiles 2202 the processor system 2204, programmable logic 2206, and/or the input/output 2208, may be optical interconnects, such as micro-LEDs and photodiodes.

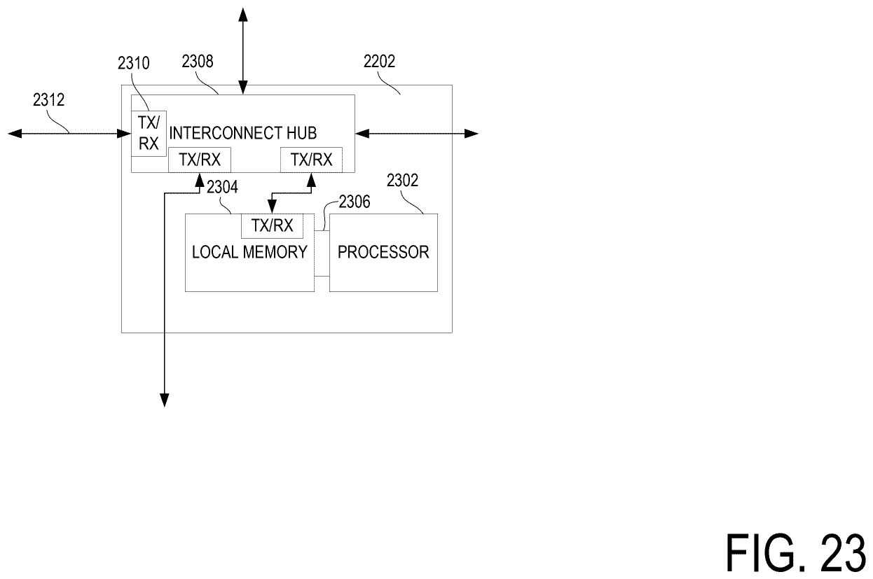

One embodiment of a compute tile 2202 is shown in FIG. 23. A compute tile 2202 includes a processor 2302, local memory 2304, local interconnect 2306, and an interconnect hub 2308. The interconnect hub 2308 may include one or more transmit/receive pairs 2310, which may be optical transceivers connected by optical links 2312 to other transmit/receive pairs 2310. The transmit/receive pairs 2310 may be similar to the micro-LED arrays 204 and the photodetector arrays 205 and the optical links 2312 may be similar to the optical cable 112 described above, which will not be repeated in the interest of clarity.

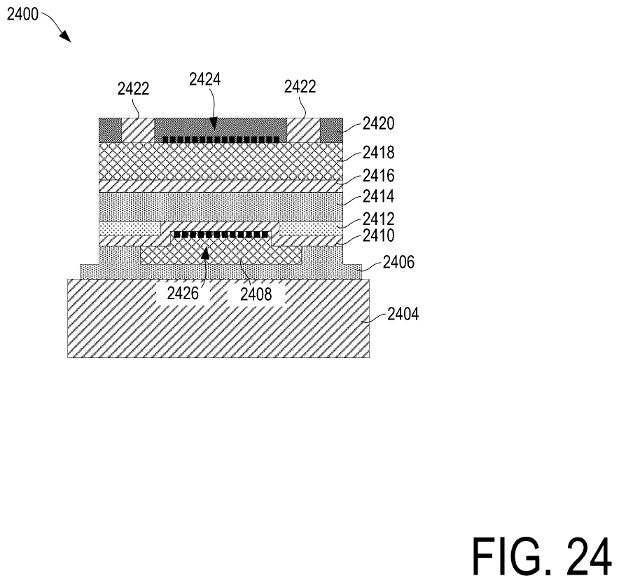

Referring now to FIG. 24, in one embodiment, a transmit/receive pair 2310 may include a photodiode 2400. The photodiode 2400 may be disposed on a substrate, such as a silicon substrate 2404. A copper contact 2406 may be used to carry a signal to or from the photodiode 2400. The photodiode 2400 includes a dielectric layer 2408, a transparent electrode 2410, a dielectric 2412, a p-doped gallium nitride layer 2414, a multi-quantum well 2416, an n-type gallium nitride layer 2418, a dielectric layer 2420, and conductive electrodes 2422. At the top of the photodiode 2400 is a first metasurface nanostructure 2424, and at the bottom of the photodiode 2400 is a second metasurface nanostructure 2426. In an illustrative embodiment, the multi-quantum well 2416 is made of undoped InGaN and GaN layers. In one embodiment, the metasurface nanostructure 2424 has a reflectivity of, e.g., 70-80%, and the metasurface nanostructure 2426 has a reflectivity near 100%. In general, the reflectivity of the metasurface nanostructure 2424 and metasurface nanostructure 2426 may be any suitable value, such as less than 1% or greater than 99.9%. The reflectivity may be wavelength-dependent, such that absorption of a target wavelength band is increased, and absorption of wavelengths outside of the target wavelength band may be reduced.

In one embodiment, the first metasurface nanostructure 2424 and the second metasurface nanostructure 2426 can improve detection efficiency at a desired wavelength and reduce sensitivity to other wavelengths, make the photodiode 2400 wavelength-selective. To do so, in an illustrative embodiment, the metasurface nanostructures 2424, 2426 have a wavelength-dependent reflectivity, and the distance between the metasurface nanostructures 2424, 2426 defines a resonance condition for certain wavelengths. The enhance absorption coefficient due to the resonance condition is given by

$${α}_{C} = {α}_{0} [ 1 + \frac{2 {ρ}_{b}}{2 π ( {t}_{q} / λ ) ( 1 + {ρ}_{b}^{2} )} sin ( 2 π \frac{{t}_{q}}{λ} ) ,$$

where t_{q} is the thickness of the quantum well absorbing layer, λ is the peak emission wavelength, α₀ is the absorption coefficient of the active layer without a cavity, and α_{c} is the effective absorption coefficient in the active layer with the cavity. Since t_{q}/λ<<1, the formula can be simplified to

$${α}_{c} \approx {α}_{0} [ 1 + \frac{2 {ρ}_{b}}{1 + {ρ}_{b}^{2}} ] .$$

$$If {ρ}_{b}^{2} = 0.81 ,$$

for example, then α_{c}≈2α₀. In other words, the absorption coefficient can be doubled due to the standing wave effect. This has positive effects on the responsivity of the metasurface photodetector.

The metasurface nanostructures 2424, 2426 can create a wavelength-dependent reflective surface by using arrays of subwavelength-sized nanoresonators (e.g., nanoscale rods, rings, or gratings) that interact with specific wavelengths of light through resonance effects. These structures may be made from any suitable material, such as metals (e.g., gold or silver) or high-refractive-index dielectrics (e.g., silicon or titanium dioxide). The structures are engineered at dimensions comparable to the target wavelength, such as tens to hundreds of nanometers, to control reflection and transmission across the desired spectrum. The metasurface nanostructures 2424, 2426 may have any suitable dimensions, such as a length and/or width of 1-1,000 micrometers and a thickness of 10-500 nanometers. The metasurface nanostructures 2424, 2426 may include a repeating two-dimensional array of subwavelength-sized resonators with a pitch of 30-300 nanometers. In some embodiments, the metasurface nanostructure may be used to control the acceptance angle of the photodetector, such as by reducing the acceptance angle, resulting in reduced crosstalk with neighboring channels.

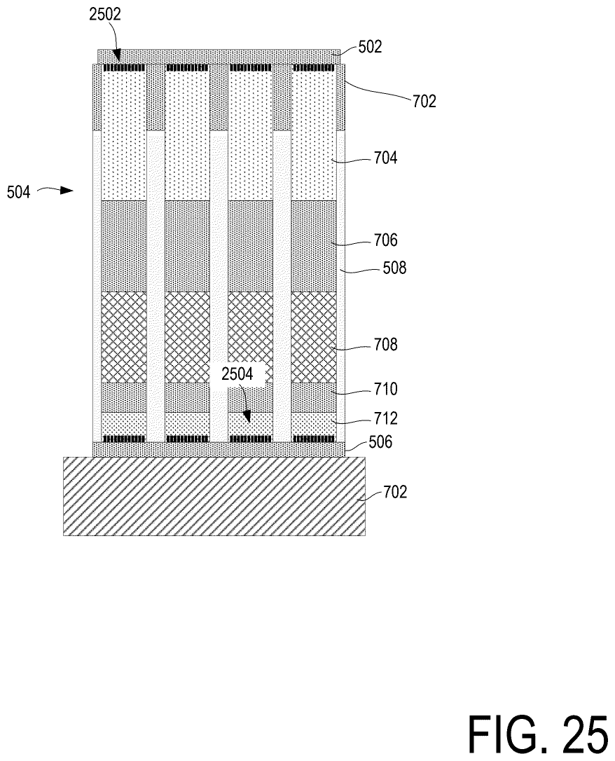

Referring now to FIG. 25, in some embodiments, nanowire phototransistors 504 may include metasurface nanostructures 2502, 2504 at the top and bottom of the nanowire phototransistors 504, as shown in the figure. The metasurface nanostructures 2502, 2504 can influence the wavelength sensitivity of the nanowire phototransistors 504 in a similar manner as the metasurface nanostructures 2424, 2426 influence the wavelength sensitivity of the photodiode 2400.

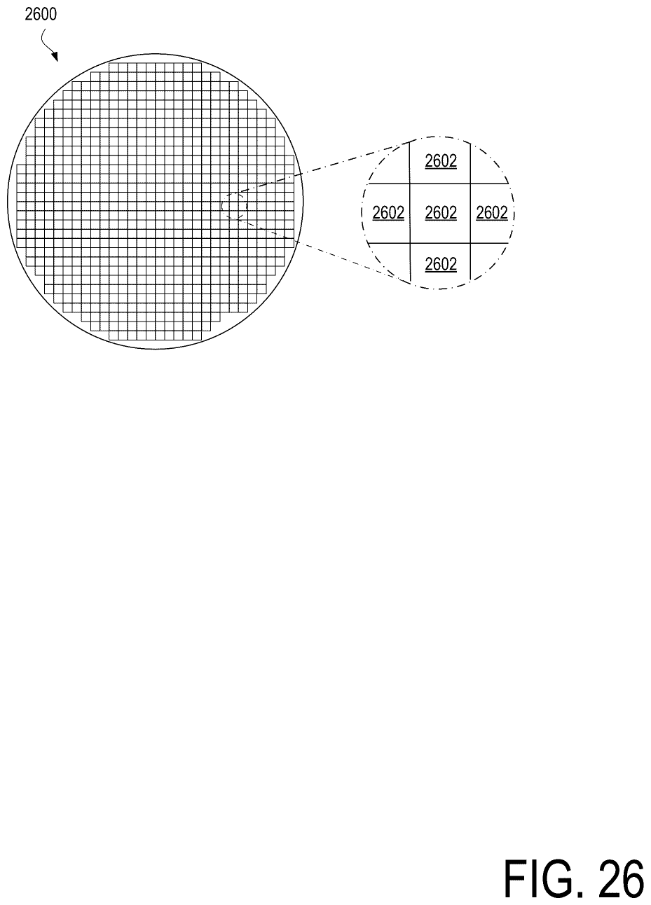

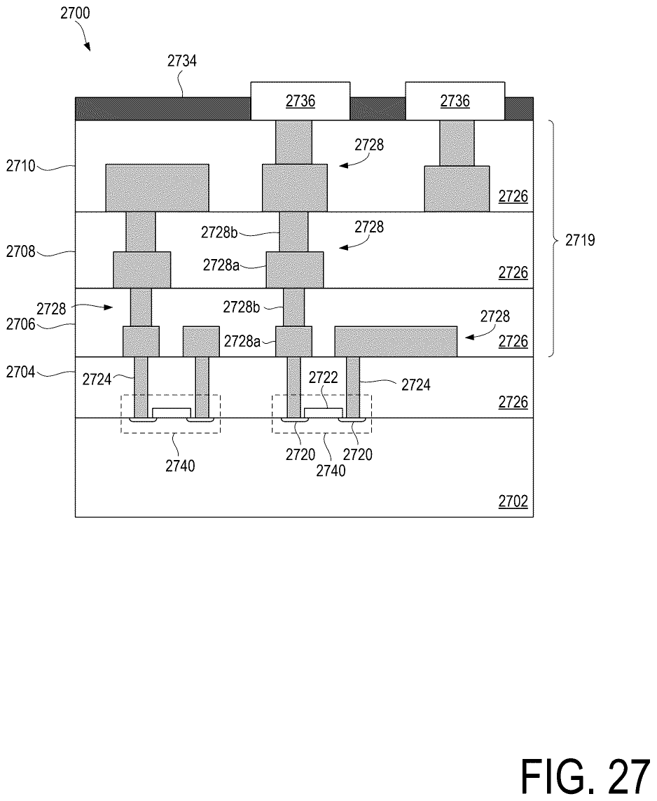

FIG. 26 is a top view of a wafer 2600 and dies 2602 that may be included in any of the integrated circuit components 102 disclosed herein (e.g., as any suitable ones of the dies 106). The wafer 2600 may be composed of semiconductor material and dies 2602 having integrated circuit structures formed on a surface of the wafer 2600. The individual dies 2602 may be a repeating unit of an integrated circuit product that includes any suitable integrated circuit. After the fabrication of the semiconductor product is complete, the wafer 2600 may undergo a singulation process in which the dies 2602 are separated from one another to provide discrete “chips” of the integrated circuit product. The dies 2602 may be any of the dies 106 disclosed herein. The dies 2602 may include one or more transistors (e.g., transistors 2740 of FIG. 27, discussed below), supporting circuitry to route electrical signals to the transistors, passive components (e.g., signal traces, resistors, capacitors, or inductors), and/or any other integrated circuit components that can be fabricated on the wafer. In some embodiments, the wafer 2600 or the dies 2602 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), logic gates (e.g., AND, OR, NAND, and NOR gates), or any other suitable circuit element. Multiple ones of these devices and components may be combined on a single die. For example, a memory array formed by multiple memory devices may be formed on the same die as a processor unit or other logic configured to store information in the memory devices or execute instructions stored in the memory array. Various ones of the integrated circuit components 102 disclosed herein may be manufactured using a die-to-wafer assembly technique in which some dies 106 are attached to a wafer 2600 that include others of the dies 106, and the wafer 2600 is subsequently singulated.

FIG. 27 is a cross-sectional view of an integrated circuit structure 2700 that may be included in any of the integrated circuit components 102 disclosed herein (e.g., in any of the dies 106). Multiple instances of the integrated circuit structure 2700 may be included in the dies 2602 (FIG. 26). The integrated circuit structure 2700 may be formed on a die substrate 2702. The die substrate 2702 may be a semiconductor substrate composed of semiconductor material including, for example, n-type or p-type materials (or a combination of both). The die substrate 2702 may include, for example, a crystalline substrate formed using a bulk silicon or a silicon-on-insulator (SOI) substructure. In some embodiments, the die substrate 2702 can comprise a layer of silicon on top of an SOI layer with bulk silicon below the SOI layer. In some embodiments, the die substrate 2702 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 2702. Although a few examples of materials from which the die substrate 2702 may be formed are described here, any material that may serve as a foundation for an integrated circuit structure 2700 may be used. The die substrate 2702 may be part of a singulated die (e.g., dies 2602 of FIG. 26) or a wafer (e.g., wafer 2600 of FIG. 26).

The integrated circuit structure 2700 may include device layer 2704 disposed on the die substrate 2702. The device layer 2704 may include features of transistors 2740 (e.g., metal oxide semiconductor field-effect transistors (MOSFETs)) formed on the die substrate 2702. The transistors 2740 may include, for example, source and drain regions (S/D regions 2720), a gate 2722 to control current flow between the S/D regions 2720, and S/D contacts 2724 to route electrical signals to and from the S/D regions 2720. The transistors 2740 may include additional features not depicted for the sake of clarity, such as device isolation regions, gate contacts, and the like. The transistors 2740 are not limited to the type and configuration depicted in FIG. 27 and may include a wide variety of other types and configurations such as, for example, non-planar transistors, or a combination of planar and non-planar transistors. Non-planar transistors may include FinFET transistors, such as double-gate transistors or tri-gate transistors, and wrap-around or all-around gate transistors, such as nanoribbon, nanosheet, or nanowire phototransistors.

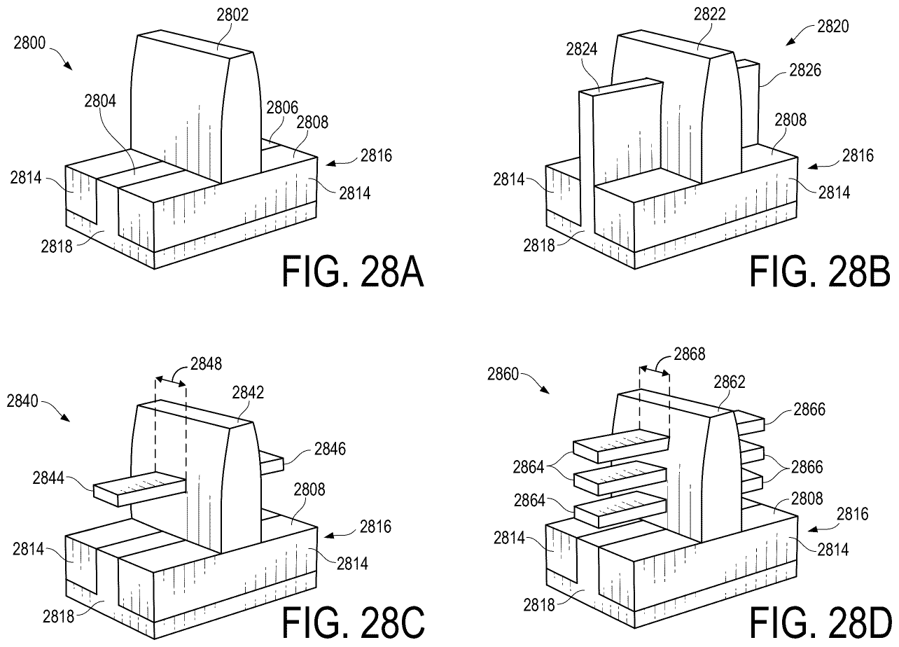

FIGS. 28A-28D are perspective views of example planar, FinFET, gate-all-around, and stacked gate-all-around transistors. The transistors illustrated in FIGS. 28A-28D are formed on a substrate 2816 having a substrate surface 2808 and a bulk region 2818. Isolation regions 2814 separate the source and drain regions of the transistors from other transistors.

FIG. 28A is a perspective view of an example transistor 2800 comprising a gate 2802 that controls current flow between a source region 2804 and a drain region 2806. The transistor 2800 is planar in that the source region 2804, the drain region 2806 and the substrate surface 2808 lie in the same plane.

FIG. 28B is a perspective view of an example transistor 2820 comprising a gate 2822 that controls current flow between a source region 2824 and a drain region 2826. The transistor 2820 is non-planar in that the source region 2824 and the drain region 2826 comprise “fins” that extend upwards from the substrate surface 2808. The transistor 2820 can be referred to as a FinFET. As the gate 2822 encompasses three sides of the fin that extends from the source region 2824 to the drain region 2826, the transistor 2820 can be considered a tri-gate transistor. FIG. 28B illustrates one S/D fin extending through the gate 2822, but multiple S/D fins can extend through the gate of a FinFET transistor.

FIG. 28C is a perspective view of a transistor 2840 comprising a gate 2842 that controls current flow between a source region 2844 and a drain region 2846. The transistor 2840 is non-planar in that the source region 2844 and the drain region 2846 lie in a different plane than the substrate surface 2808. As the gate 2842 encompasses all sides of the channel region of the transistor 2840 that extends from the source region 2844 to the drain region 2846, the transistor 2840 can be referred to as a gate-all-around (GAA) transistor.

FIG. 28D is a perspective view of a transistor 2860 comprising a gate 2862 that controls current flow between multiple elevated source regions 2864 and multiple elevated drain regions 2866. The transistor 2860 is a stacked GAA transistor as the gate controls the flow of current between multiple elevated S/D regions stacked on top of each other. The transistors 2840 and 2860 are considered gate-all-around transistors as the gates encompass all sides of the channel regions of the transistor that extends from the source regions to the drain regions. The transistors 2840 and 2860 can alternatively be referred to as nanowire, nanosheet, or nanoribbon transistors depending on the width (e.g., widths 2848 and 2868 of transistors 2840 and 2860, respectively) of the channel regions extending through the gate.

Returning to FIG. 27, transistors 2740 may include a gate 2722 formed of at least two layers, a gate dielectric, and a gate electrode. The gate dielectric may include one or more layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For PMOS transistors, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For NMOS transistors, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, such as in the FinFET illustrated in FIG. 28B, the gate electrode may have an upside-down U-shape that includes a top portion substantially parallel to the surface of the die substrate 2702 and two side portions that are substantially perpendicular to the top surface of the die substrate 2702. In other embodiments, such as the planar FET illustrated in FIG. 28A, at least one of the metal layers that form the gate electrode may be a planar layer that is substantially parallel to the top surface of the die substrate 2702 without side portions. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack (comprising the gate dielectric and the gate electrode) to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of sidewall spacer pairs may be used; for instance, two pairs, three pairs, or four pairs of sidewall spacers may be formed on opposing sides of the gate stack.

The S/D regions 2720 may be formed within the die substrate 2702 adjacent to the gate 2722 of transistors 2740. The S/D regions 2720 may be formed using an implantation/diffusion process or an etching/deposition process, for example. In the former process, dopants such as boron, aluminum, antimony, phosphorous, or arsenic may be ion-implanted into the die substrate 2702 to form the S/D regions 2720. An annealing process that activates the dopants and causes them to diffuse further into the die substrate 2702 may follow the ion implantation process. In the latter process, the die substrate 2702 may first be etched to form recesses at the locations of the S/D regions 2720. An epitaxial deposition process may then be carried out to fill the recesses with material that is used to fabricate the S/D regions 2720. In some implementations, the S/D regions 2720 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 2720 may be formed using one or more alternate semiconductor materials such as germanium or a group III-V material or alloy. In further embodiments, one or more layers of metal and/or metal alloys may be used to form the S/D regions 2720.

Electrical signals, such as power and/or information-carrying signals (e.g., input/output (I/O) signals, may be routed to and/or from devices (e.g., transistors 2740) of the device layer 2704 through one or more interconnect layers disposed on the device layer 2704 (illustrated in FIG. 27 as interconnect layers 2706-2710). For example, electrically conductive features of the device layer 2704 (e.g., the gate 2722 and the S/D contacts 2724) may be electrically coupled with interconnect structures 2728 of the interconnect layers 2706-2710. The one or more interconnect layers 2706-2710 may form a metallization stack 2719 (which can also be referred to as an “ILD stack” (inter-layer dielectric stack)) of the integrated circuit structure 2700.

The interconnect structures 2728 may be arranged within the interconnect layers 2706-2710 to route electrical signals according to a wide variety of designs; in particular, the arrangement is not limited to the particular configuration of interconnect structures 2728 depicted in FIG. 27. Although a particular number of interconnect layers 2706-2710 is depicted in FIG. 27, embodiments of the present disclosure include integrated circuit structures having more or fewer interconnect layers than depicted.

In some embodiments, the interconnect structures 2728 may include traces or lines 2728a and/or vias 2728b filled with an electrically conductive material such as a metal. The lines 2728a may be arranged to route electrical signals in a direction of a plane that is substantially parallel with a surface of the die substrate 2702 upon which the device layer 2704 is formed. For example, the lines 2728a may route electrical signals in a direction in and out of the page and/or in a direction across the page from the perspective of FIG. 27. The vias 2728b may be arranged to route electrical signals in a direction of a plane that is substantially perpendicular to the surface of the die substrate 2702 upon which the device layer 2704 is formed. In some embodiments, lines 2728a of different interconnect layers 2706-2710 are electrically coupled by vias 2728b.

The interconnect layers 2706-2710 may include a dielectric material 2726 within which the interconnect structures 2728 are disposed, as shown in FIG. 27. In some embodiments, dielectric material 2726 in different ones of the interconnect layers 2706-2710 may have different compositions; in other embodiments, the composition of the dielectric material 2726 between different interconnect layers 2706-2710 may be the same. The device layer 2704 may include a dielectric material 2726 within which the transistors 2740 are disposed and upon which a bottom layer of the metallization stack is located. The dielectric material 2726 that is part of the device layer 2704 may have a different composition than the dielectric material 2726 included in the interconnect layers 2706-2710; in other embodiments, the composition of the dielectric material 2726 in the device layer 2704 may be the same as a dielectric material 2726 included in any one of the interconnect layers 2706-2710.

A first interconnect layer 2706 (which can be referred to as a Metal 1 or “M1” layer) may be formed directly on the device layer 2704. In some embodiments, the first interconnect layer 2706 may include lines 2728a and/or vias 2728b, as shown. The lines 2728a of the first interconnect layer 2706 may be coupled with contacts (e.g., the S/D contacts 2724) of the device layer 2704. The vias 2728b of the first interconnect layer 2706 may be coupled with the lines 2728a of a second interconnect layer 2708.

The second interconnect layer 2708 (which can be referred to as a Metal 2 or “M2” layer) may be formed directly on the first interconnect layer 2706. In some embodiments, the second interconnect layer 2708 may include vias 2728b to couple the lines 2728a of the second interconnect layer 2708 with the lines 2728a of a third interconnect layer 2710. Although the lines 2728a and the vias 2728b are structurally delineated with a line within individual interconnect layers for the sake of clarity, the lines 2728a and the vias 2728b may be structurally and/or materially contiguous (e.g., simultaneously filled during a dual-damascene process) in some embodiments.

The third interconnect layer 2710 (which can be referred to as a Metal 3 or “M3” layer) (and additional interconnect layers, as desired) may be formed in succession on the second interconnect layer 2708 according to similar techniques and configurations described in connection with the second interconnect layer 2708 or the first interconnect layer 2706. In some embodiments, the interconnect layers that are “higher up” in the metallization stack 2719 in the integrated circuit structure 2700 (i.e., farther away from the device layer 2704) may be thicker than the interconnect layers that are lower in the metallization stack 2719, with lines 2728a and vias 2728b in the higher interconnect layers being thicker than those in the lower interconnect layers.

The integrated circuit structure 2700 may include a solder resist material 2734 (e.g., polyimide or similar material) and conductive contacts 2736 formed on the stack of interconnect layers 2706-2710. In FIG. 27, the conductive contacts 2736 are illustrated as taking the form of bond pads. The conductive contacts 2736 may be electrically coupled with interconnect structures 2728 of the top-most layer in the metallization stack 2719 and configured to route electrical signals between the transistors 2740 and components external to the integrated circuit structure 2700. For example, solder bonds may be formed on the conductive contacts 2736 to mechanically and/or electrically couple an integrated circuit component comprising the integrated circuit structure 2700 with another component (e.g., a printed circuit board). The integrated circuit structure 2700 may include additional or alternate structures to route electrical signals from the interconnect layers 2706-2710; for example, the conductive contacts 2736 may include other analogous features (e.g., posts) that can route the electrical signals between the transistors 2740 and external components.

In some embodiments in which the integrated circuit structure 2700 is part of a double-sided die the integrated circuit structure 2700 may include a second metallization stack (not shown) located on the opposite side of the die substrate 2702 from the device layer 2704. This second metallization stack may include multiple interconnect layers as discussed above with reference to the interconnect layers 2706-2710. Through-silicon vias (TSVs) that extend through the die substrate 2702 can provide electrically conductive pathways from the transistors 2740 to the second metallization stack and the second metallization stack can electrically couple the TSVs to additional conductive contacts (not shown) located on the opposite side of the integrated circuit structure 2700 from the conductive contacts 2736.

In some embodiments, TSVs extending through the die substrate 2702 can be used for routing power and ground signals from conductive contacts located on the opposite side of the integrated circuit structure 2700 from the conductive contacts 2736 to the transistors 2740 and any other components integrated into the integrated circuit structure 2700, and the metallization stack 2719 can be used to route information-carrying signals from the conductive contacts 2736 to transistors 2740 and any other components integrated into the integrated circuit structure 2700. Put another way, the routing of power and ground signals to the transistors 2740 can be separated (via a back-side or bottom-side metallization stack and TSVs) from the routing of information-carrying signals to the transistors. The power and ground signals are provided by a back-side or bottom-side metallization stack and TSVs, and information-carrying signals are provide by a top-side metallization stack (e.g., metallization stack 2719).

Several integrated circuit dies may be stacked with one or more TSVs in the individual stacked dies providing connection between one of the dies to any of the other dies in the stack. For example, one or more high-bandwidth memory (HBM) integrated circuit dies can be stacked on top of a base integrated circuit die and TSVs in the HBM dies can provide connection between the individual HBM dies and the base integrated circuit die. Conductive contacts can provide additional connections between adjacent integrated circuit dies in the stack. In some embodiments, the conductive contacts can be fine-pitch solder bumps (microbumps).

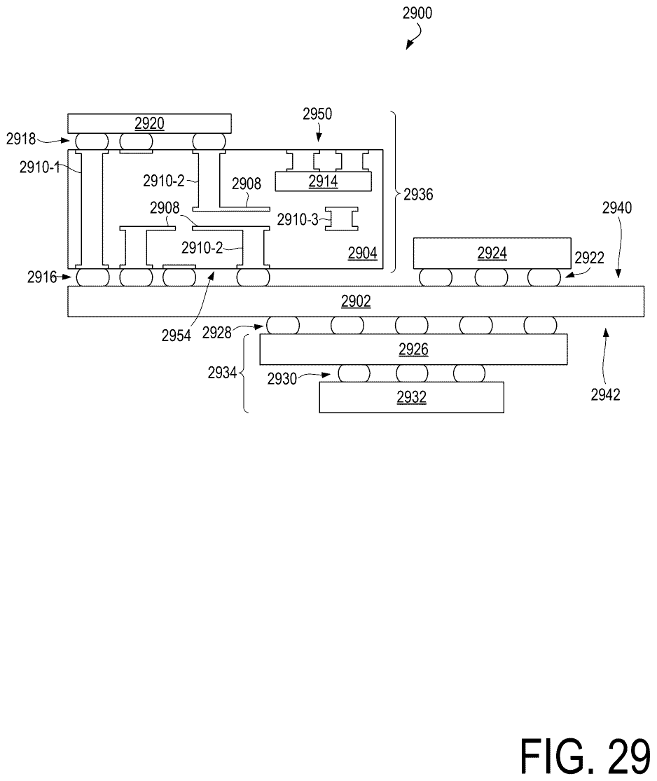

FIG. 29 is a cross-sectional view of an integrated circuit device assembly 2900 that may include any of the integrated circuit components 102 disclosed herein. In some embodiments, the integrated circuit device assembly 2900 may be a integrated circuit components 102. The integrated circuit device assembly 2900 includes a number of components disposed on a circuit board 2902 (which may be a motherboard, system board, mainboard, etc.). The integrated circuit device assembly 2900 includes components disposed on a first face 2940 of the circuit board 2902 and a second face 2942 of the circuit board 2902, the second face 2942 opposing the first face 2940. Generally, components may be disposed on either or both of the first face 2940 and the second face 2942 of the circuit board 2902. Any of the integrated circuit components discussed below with reference to the integrated circuit device assembly 2900 may take the form of any suitable ones of the embodiments of the integrated circuit components 102 disclosed herein.

In some embodiments, the circuit board 2902 may be a printed circuit board (PCB) including multiple metal (or interconnect) layers separated from one another by layers of dielectric material and interconnected by electrically conductive vias. The individual metal layers comprise conductive traces. The metal layers may be formed in a desired pattern to route electrical signals between the components electrically coupled to the circuit board 2902. In other embodiments, the circuit board 2902 may be a non-PCB substrate. In some embodiments the circuit board 2902 may be, for example, the circuit board 104.

The integrated circuit device assembly 2900 illustrated in FIG. 29 includes a package-on-interposer structure 2936 coupled to the first face 2940 of the circuit board 2902 by coupling components 2916. The coupling components 2916 may electrically and mechanically couple the package-on-interposer structure 2936 to the circuit board 2902 and may include solder balls (as shown in FIG. 29), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. (Thus, a coupling component may comprise a conductive contact.) The coupling components 2916 may serve as the coupling components illustrated or described for any substrate assembly or substrate assembly components described herein (e.g., integrated circuit components), as appropriate.

The package-on-interposer structure 2936 may include an integrated circuit component 2920 coupled to an interposer 2904. The interposer 2904 may provide an intervening substrate used to bridge the circuit board 2902 and the integrated circuit component 2920. The integrated circuit component 2920 is coupled to the interposer 2904 by coupling components 2918. The coupling components 2918 may take any suitable form, such as the forms discussed above with reference to the coupling components 2916. Although FIG. 29 shows just one integrated circuit component attached to the interposer, multiple integrated circuit components may be coupled to the interposer 2904. Additional interposers may be coupled to the interposer 2904.

The integrated circuit component 2920 may be a packaged or unpacked integrated circuit product that includes one or more integrated circuit dies (e.g., the die 2602 of FIG. 26, a die comprising the integrated circuit structure 2700 of FIG. 27) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one unpackaged example of an integrated circuit component 2920, a single monolithic integrated circuit die comprises solder bumps attached to contacts on the die. The solder bumps allow the die to be directly attached to the interposer 2904. The integrated circuit component 2920 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 2920 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 2920 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 2920 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 2904 may spread connections to a wider or narrower pitch or reroute a connection to a different connection. For example, the interposer 2904 may couple coupling components 2918 having a first pitch to coupling components 2916 having a wider pitch than the first pitch. In the embodiment illustrated in FIG. 29, the integrated circuit component 2920 and the circuit board 2902 are attached to opposing sides of the interposer 2904. In other embodiments, the integrated circuit component 2920 and the circuit board 2902 may be attached to a same side of the interposer 2904. In some embodiments, three or more components may be interconnected by way of the interposer 2904.

In some embodiments, the interposer 2904 may be formed as a PCB, including multiple metal layers separated from one another by layers of dielectric material and interconnected by electrically conductive vias. In some embodiments, the interposer 2904 may be formed of an epoxy resin, a fiberglass-reinforced epoxy resin, an epoxy resin with inorganic fillers, a ceramic material, or a polymer material such as polyimide. In some embodiments, the interposer 2904 may be formed of alternate rigid or flexible materials that may include the same materials described above for use in a semiconductor substrate, such as silicon, germanium, and other group III-V and group IV materials. The interposer 2904 may include metal interconnects 2908 and vias, including but not limited to through hole vias 2910-1 (that extend from a first face 2950 of the interposer 2904 to a second face 2954 of the interposer 2904), blind vias 2910-2 (that extend from the first face 2950 or the second face 2954 of the interposer 2904 to an internal metal layer), and buried vias 2910-3 (that connect internal metal layers).

In some embodiments, the interposer 2904 can comprise a silicon interposer. Through silicon vias (TSV) extending through the silicon interposer can connect connections on a first face of a silicon interposer to an opposing second face of the silicon interposer. In some embodiments, an interposer 2904 comprising a silicon interposer can further comprise one or more routing layers to route connections on a first face of the interposer 2904 to an opposing second face of the interposer 2904.

In some embodiments the interposer 2904, as well as the circuit board 2902, can comprise an amorphous solid layer of glass (which can be referred to a glass core or glass substrate). In some embodiments, the layer of glass can comprise silica (comprising silicon dioxide (SiO₂)), fused silica, aluminosilicate (comprising aluminum oxide (Al₂O₃) and silicon dioxide), borosilicate (comprising silicon dioxide and boron trioxide (B₂O₃)), or alumino-borosilicate (comprising aluminum oxide, silicon dioxide, and boron trioxide). In some embodiments, the layer of glass can comprise one or more of the following additives: aluminum oxide, boron trioxide, magnesium oxide (MgO), calcium oxide (CaO), strontium oxide (SrO), barium oxide (BaO), tin(IV) oxide (SnO₂), nitrous oxide (Na₂O), potassium oxide (K₂O), diphosphorous trioxide (P₂O₃), zirconium dioxide (ZrO₂), lithium oxide (Li₂O), titanium, and zinc. In some embodiments, the layer of glass can comprise silicon and oxygen, as well as one or more of aluminum, boron, magnesium, calcium, barium, tin, sodium, potassium, strontium, phosphorous, zirconium, lithium, titanium, and zinc. In some embodiments, the layer of glass comprises at least 23 percent silicon by weight, at least 26 percent oxygen by weight, and at least five percent aluminum by weight. In some embodiments, the layer of glass does not include an organic adhesive or an organic material. For example, the layer of glass is not a substrate or a board comprising glass fibers and an epoxy binder, such as a printed circuit board (PCB) comprising multiple metal (or interconnect) layers separated from one another by layers of dielectric material (e.g., FR-4 or other fiberglass-reinforced epoxy laminate) and interconnected by electrically conductive vias.

In some embodiments, the glass layer has a thickness in the range of about 50 microns to about 1.4 millimeters. In some embodiments, the glass layer is or is part of a multi-layer glass substrate (a coreless substrate). Individual glass layers in a multi-layer glass substrate can have a thickness in the range of about 25 microns to about 50 microns. In some embodiments, a glass layer can have a length in the range of about 10 millimeters to about 250 millimeters on a side (e.g., can have an area in the range of about 10 mm×10 mm to about 250 mm×250 mm). In some embodiments, the glass layer comprises a rectangular prism volume with sections or portions (e.g., through-glass vias) removed and filled with other metals (e.g., metal).

In some embodiments, redistribution layers (RDL) can be located on either or both sides of the glass layer to provide electrically conductive paths from top and/or bottom surfaces of the interposer 2904 or circuit board 2902 to the glass layer. The glass layer can comprise through-glass vias (TGVs) that extend through the glass layer to provide electrically conductive paths through the glass core, glass substrate, or glass layer.

The interposer 2904 may further include embedded devices 2914, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 2904. The package-on-interposer structure 2936 may take the form of any of the package-on-interposer structures known in the art.

The integrated circuit device assembly 2900 may include an integrated circuit component 2924 coupled to the first face 2940 of the circuit board 2902 by coupling components 2922. The coupling components 2922 may take the form of any of the embodiments discussed above with reference to the coupling components 2916, and the integrated circuit component 2924 may take the form of any of the embodiments discussed above with reference to the integrated circuit component 2920.

The integrated circuit device assembly 2900 illustrated in FIG. 29 further includes a package-on-package structure 2934 coupled to the second face 2942 of the circuit board 2902 by coupling components 2928. The package-on-package structure 2934 may include an integrated circuit component 2926 and an integrated circuit component 2932 coupled together by coupling components 2930 such that the integrated circuit component 2926 is disposed between the circuit board 2902 and the integrated circuit component 2932. The coupling components 2928 and 2930 may take the form of any of the embodiments of the coupling components 2916 discussed above, and the integrated circuit components 2926 and 2932 may take the form of any of the embodiments of the integrated circuit component 2920 discussed above. The package-on-package structure 2934 may be configured in accordance with any of the package-on-package structures known in the art.

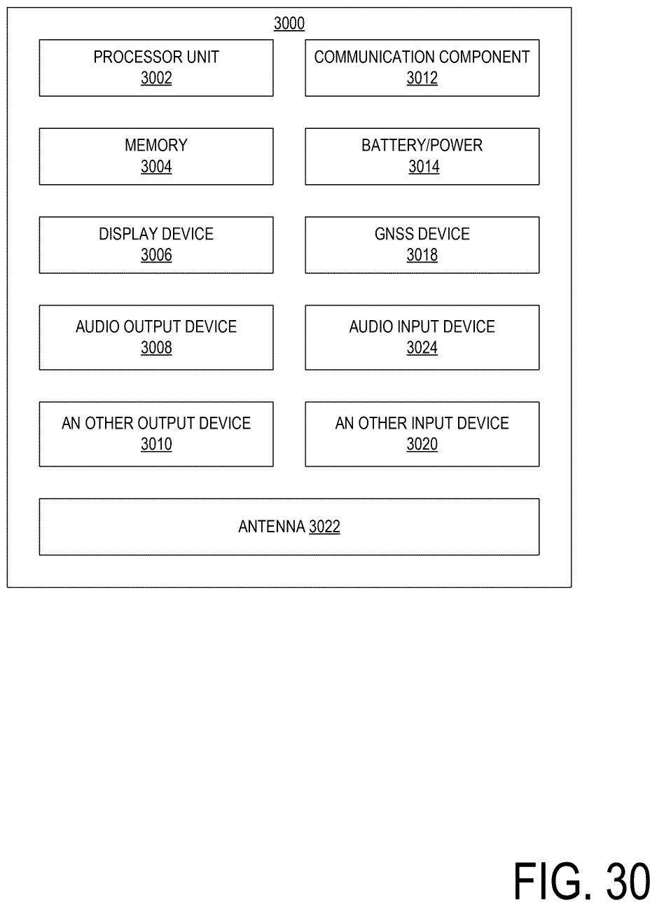

FIG. 30 is a block diagram of an example electrical device 3000 that may include any of the microelectronic assemblies disclosed herein. For example, any suitable ones of the components of the electrical device 3000 may include one or more of the integrated circuit device assembly 2900, integrated circuit component 2920, or integrated circuit structure 2700, integrated circuit dies 2602 disclosed herein, and may be arranged in any of the integrated circuit components 102 disclosed herein. A number of components are illustrated in FIG. 30 as included in the electrical device 3000, but any one or more of these components may be omitted or duplicated, as suitable for the application. In some embodiments, some or all of the components included in the electrical device 3000 may be attached to one or more motherboards mainboards, or system boards. In some embodiments, one or more of these components are fabricated onto a single system-on-a-chip (SoC) die.

Additionally, in various embodiments, the electrical device 3000 may not include one or more of the components illustrated in FIG. 30, but the electrical device 3000 may include interface circuitry for coupling to the one or more components. For example, the electrical device 3000 may not include a display device 3006, but may include display device interface circuitry (e.g., a connector and driver circuitry) to which a display device 3006 may be coupled. In another set of examples, the electrical device 3000 may not include an audio input device 3024 or an audio output device 3008, but may include audio input or output device interface circuitry (e.g., connectors and supporting circuitry) to which an audio input device 3024 or audio output device 3008 may be coupled.

The electrical device 3000 may include one or more processor units 3002. As used herein, the terms “processor unit,” “processing unit,” or “processor” may refer to any device or portion of a device that processes electronic data from registers and/or memory to transform that electronic data into other electronic data that may be stored in registers and/or memory. The one or more processor units 3002 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 3000 may include a memory 3004, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 3004 may include memory that is located on the same integrated circuit die as the one or more processor units 3002. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments of the electrical device 3000, a first one of the one or more processor units 3002 can be heterogeneous or asymmetric to a second one of the one or more processor units 3002 in the electrical device 3000. There can be a variety of differences between the one or more processor units 3002 in a system in terms of a spectrum of metrics of merit including architectural, microarchitectural, thermal, power consumption characteristics, and the like. These differences can effectively manifest themselves as asymmetry and heterogeneity among the one or more processor units 3002 in the electrical device 3000.

In some embodiments, the electrical device 3000 may include a communication component 3012. For example, the communication component 3012 can manage wireless communications for the transfer of data to and from the electrical device 3000. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 3012 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 3012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 3012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 3012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 3012 may operate in accordance with other wireless protocols in other embodiments. The electrical device 3000 may include an antenna 3022 to facilitate wireless communications and/or to receive other wireless communications (such as AM or FM radio transmissions).

In some embodiments, the communication component 3012 may manage wired communications, such as electrical, optical, or any other suitable communication protocols (e.g., IEEE 802.3 Ethernet standards). In some embodiments, the electrical device 3000 comprises multiple communication components. For instance, a first communication component may be dedicated to shorter-range wireless communications such as Wi-Fi or Bluetooth, and a second communication component may be dedicated to longer-range wireless communications such as global positioning system (GPS), EDGE, GPRS, CDMA, WiMAX, LTE, EV-DO, or others. In some embodiments, a first communication component may be dedicated to wireless communications, and a second communication component may be dedicated to wired communications.

The electrical device 3000 may include battery/power circuitry 3014. The battery/power circuitry 3014 may include one or more energy storage devices (e.g., batteries or capacitors) and/or circuitry for coupling components of the electrical device 3000 to an energy source separate from the electrical device 3000 (e.g., AC line power).

The electrical device 3000 may include a display device 3006 (or corresponding interface circuitry, as discussed above). The display device 3006 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 3000 may include an audio output device 3008 (or corresponding interface circuitry, as discussed above). The audio output device 3008 may include any embedded or wired or wirelessly connected external device that generates an audible indicator, such as speakers, headsets, or earbuds.

The electrical device 3000 may include an audio input device 3024 (or corresponding interface circuitry, as discussed above). The audio input device 3024 may include any embedded or wired or wirelessly connected device that generates a signal representative of a sound, such as microphones, microphone arrays, or digital instruments (e.g., instruments having a musical instrument digital interface (MIDI) output). The electrical device 3000 may include a Global Navigation Satellite System device (GNSS) (or corresponding interface circuitry, as discussed above), such as a Global Positioning System (GPS) device. The GNSS device 3018 may be in communication with a satellite-based system and may determine a geolocation of the electrical device 3000 based on information received from one or more GNSS satellites, as known in the art.

The electrical device 3000 may include another output device 3010 (or corresponding interface circuitry, as discussed above). Examples of the other output device 3010 may include an audio codec, a video codec, a printer, a wired or wireless transmitter for providing information to other devices, or an additional storage device.

The electrical device 3000 may include another input device 3020 (or corresponding interface circuitry, as discussed above). Examples of the other input device 3020 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 3000 may have any form factor, such as a hand-held or mobile electrical device (e.g., a cell phone, a smartphone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console), a desktop electrical device, a server, a rack-level computing solution (e.g., blade, tray, or sled computing system), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment), a router, a network switch, etc. In some embodiments, the electrical device 3000 may be any other electronic device that processes data. In some embodiments, the electrical device 3000 may comprise multiple discrete physical components. Given the range of devices that the electrical device 3000 can be manifested as in various embodiments, in some embodiments, the electrical device 3000 can be referred to as a computing device or a computing system.

### Examples

Illustrative examples of the technologies disclosed herein are provided below. An embodiment of the technologies may include any one or more, and any combination of, the examples described below.

Example 1 includes an apparatus comprising an integrated circuit die, the integrated circuit die comprising a substrate; a first electrode; a second electrode; and a plurality of nanowire phototransistors extending from the substrate, wherein individual nanowire phototransistors of the plurality of nanowire phototransistors comprise an emitter, a multi-quantum well, and a collector, wherein the emitter of individual nanowire phototransistors of the plurality of nanowire phototransistors are electrically coupled to the first electrode, wherein the collector of individual nanowire phototransistors of the plurality of nanowire phototransistors are electrically coupled to the second electrode.

Example 2 includes the subject matter of Example 1, and wherein the integrated circuit die further comprises a photodetector array, the photodetector array comprising a plurality of pixels, wherein individual pixels of the plurality of pixels comprise a plurality of nanowire phototransistors, wherein the plurality of nanowire phototransistors of individual pixels of the plurality of pixels share a common emitter electrode and a common collector electrode.

Example 3 includes the subject matter of any of Examples 1 and 2, and wherein individual nanowire phototransistors of the plurality of nanowire phototransistors further comprise a floating base.

Example 4 includes the subject matter of any of Examples 1-3, and wherein the plurality of nanowire phototransistors form a photonic crystal.

Example 5 includes the subject matter of any of Examples 1-4, and wherein the photonic crystal establishes an acceptance angle for the plurality of nanowire phototransistors.

Example 6 includes the subject matter of any of Examples 1-5, and wherein the photonic crystal establishes a wavelength sensitivity range for the plurality of nanowire phototransistors.

Example 7 includes the subject matter of any of Examples 1-6, and further including a multi-mode fiber, wherein an output of the multi-mode fiber is coupled to the plurality of nanowire phototransistors.

Example 8 includes the subject matter of any of Examples 1-7, and wherein a plurality of micro-LEDs at a plurality of wavelengths are coupled to an input of the multi-mode fiber.

Example 9 includes the subject matter of any of Examples 1-8, and further including one or more optical filters to filter one or more wavelengths of light from the plurality of nanowire phototransistors.

Example 10 includes the subject matter of any of Examples 1-9, and wherein the one or more optical filters comprise a metasurface nanostructure.

Example 11 includes the subject matter of any of Examples 1-10, and further including a first optical filter above the plurality of nanowire phototransistors and a second optical filter below the plurality of nanowire phototransistors, wherein the first optical filter and the second optical filter establish a resonant cavity.

Example 12 includes the subject matter of any of Examples 1-11, and wherein, for individual nanowire phototransistors of the plurality of nanowire phototransistors, the emitter comprises gallium and nitrogen, the multi-quantum well comprises indium, gallium, and nitrogen, a collector comprises gallium and nitrogen, and a base comprises indium gallium and nitrogen.

Example 13 includes the subject matter of any of Examples 1-12, and wherein, for individual nanowire phototransistors of the plurality of nanowire phototransistors, the emitter comprises silicon, the multi-quantum well comprises silicon and germanium, a collector comprises silicon, and a base comprises silicon and germanium.

Example 14 includes the subject matter of any of Examples 1-13, and further including an optical receptacle mounted on the integrated circuit die, wherein the optical receptacle is to align an optical plug to couple light to the plurality of nanowire phototransistors.

Example 15 includes the subject matter of any of Examples 1-14, and further including the optical plug, wherein the optical plug is mated with the optical receptacle; and one or more optical fiber cores, wherein the one or more optical fiber cores terminate at the optical plug, wherein individual optical fiber cores of the one or more optical fiber cores are aligned to the plurality of nanowire phototransistors.

Example 16 includes the subject matter of any of Examples 1-15, and further including a network switch, the network switch including a circuit board, wherein the integrated circuit die is mounted on the circuit board.

Example 17 includes an apparatus comprising an integrated circuit die, the integrated circuit die comprising a substrate; and a plurality of photodetectors extending from the substrate, further comprising, for individual photodetectors of the plurality of photodetectors, a first metasurface nanostructure above the photodetector and a second metasurface nanostructure below the photodetector, wherein, for individual photodetectors of the plurality of photodetectors, the first metasurface nanostructure and the second metasurface nanostructure form a resonant cavity that at least partially overlaps with the photodetector.

Example 18 includes the subject matter of Example 17, and wherein, for individual photodetectors of the plurality of photodetectors, the resonant cavity increases a detection efficiency of the photodetector by at least a factor of 1.5.

Example 19 includes the subject matter of any of Examples 17 and 18, and wherein, for individual photodetectors of the plurality of photodetectors, the resonant cavity rejects one or more wavelengths outside of a target wavelength band.

Example 20 includes the subject matter of any of Examples 17-19, and wherein, for individual photodetectors of the plurality of photodetectors, the first metasurface nanostructure establishes an acceptance angle for the photodetector.

Example 21 includes the subject matter of any of Examples 17-20, and wherein, for individual photodetectors of the plurality of photodetectors, the first metasurface nanostructure has a length and width of at least 2 micrometers and comprises a two-dimensional array of nanoresonators, the two-dimensional array of nanoresonators having a pitch between 30-300 nanometers.

Example 22 includes the subject matter of any of Examples 17-21, and wherein the plurality of photodetectors comprise a plurality of photodiodes.

Example 23 includes the subject matter of any of Examples 17-22, and wherein individual photodiodes of the plurality of photodetectors comprise a p-doped region, an intrinsic region, and an n-doped region, the intrinsic region comprising a multi-quantum well.

Example 24 includes the subject matter of any of Examples 17-23, and wherein the plurality of photodetectors comprise a plurality of nanowire phototransistors.

Example 25 includes the subject matter of any of Examples 17-24, and wherein individual nanowire phototransistors of the plurality of nanowire phototransistors further comprise a floating base.

Example 26 includes the subject matter of any of Examples 17-25, and wherein the plurality of nanowire phototransistors form a photonic crystal.

Example 27 includes the subject matter of any of Examples 17-26, and wherein the photonic crystal establishes an acceptance angle for the plurality of nanowire phototransistors.

Example 28 includes the subject matter of any of Examples 17-27, and wherein the photonic crystal establishes a wavelength sensitivity range for the plurality of nanowire phototransistors.

Example 29 includes the subject matter of any of Examples 17-28, and further including a multi-mode fiber, wherein an output of the multi-mode fiber is coupled to the plurality of photodetectors.

Example 30 includes the subject matter of any of Examples 17-29, and wherein a plurality of micro-LEDs at a plurality of wavelengths are coupled to an input of the multi-mode fiber.

Example 31 includes the subject matter of any of Examples 17-30, and further including an optical receptacle mounted on the integrated circuit die, wherein the optical receptacle is to align an optical plug to couple light to the plurality of photodetectors.

Example 32 includes the subject matter of any of Examples 17-31, and further including the optical plug, wherein the optical plug is mated with the optical receptacle; and one or more optical fiber cores, wherein the one or more optical fiber cores terminate at the optical plug, wherein individual optical fiber cores of the one or more optical fiber cores are aligned to the plurality of photodetectors.

Example 33 includes the subject matter of any of Examples 17-32, and further including a circuit board, wherein the integrated circuit die is mounted on the circuit board.

Example 34 includes a method comprising forming a release layer on a substrate; creating a plurality of nanowire phototransistors on the release layer; attaching a second substrate to the plurality of nanowire phototransistors; and releasing the release layer.

Example 35 includes the subject matter of Example 34, and wherein the second substrate further comprises a photodetector array, the photodetector array comprising a plurality of pixels, wherein individual pixels of the plurality of pixels comprise a plurality of nanowire phototransistors, wherein the plurality of nanowire phototransistors of individual pixels of the plurality of pixels share a common emitter electrode and a common collector electrode.

Example 36 includes the subject matter of any of Examples 34 and 35, and wherein individual nanowire phototransistors of the plurality of nanowire phototransistors further comprise a floating base.

Example 37 includes the subject matter of any of Examples 34-36, and wherein the plurality of nanowire phototransistors form a photonic crystal.

Example 38 includes the subject matter of any of Examples 34-37, and wherein the photonic crystal establishes an acceptance angle for the plurality of nanowire phototransistors.

Example 39 includes the subject matter of any of Examples 34-38, and wherein the photonic crystal establishes a wavelength sensitivity range for the plurality of nanowire phototransistors.

Example 40 includes the subject matter of any of Examples 34-39, and further including forming one or more optical filters to filter one or more wavelengths of light from the plurality of nanowire phototransistors.

Example 41 includes the subject matter of any of Examples 34-40, and wherein the one or more optical filters comprise a metasurface nanostructure.

Example 42 includes the subject matter of any of Examples 34-41, and further including forming a first optical filter above the plurality of nanowire phototransistors and a second optical filter below the plurality of nanowire phototransistors, wherein the first optical filter and the second optical filter establish a resonant cavity.

Example 43 includes the subject matter of any of Examples 34-42, and wherein, individual nanowire phototransistors of the plurality of nanowire phototransistors comprise an emitter, a multi-quantum well, a collector, and a base, the emitter comprising gallium and nitrogen, the multi-quantum well comprising indium, gallium, and nitrogen, and the collector comprising gallium and nitrogen, and a base comprises indium gallium and nitrogen.

Example 44 includes the subject matter of any of Examples 34-43, and wherein, individual nanowire phototransistors of the plurality of nanowire phototransistors comprise an emitter, a multi-quantum well, a collector, and a base, the emitter comprising silicon, the multi-quantum well comprising silicon and germanium, the collector comprising silicon, and the base comprising silicon and germanium.

1. An apparatus comprising:
an integrated circuit die, the integrated circuit die comprising a substrate;
a first electrode;
a second electrode; and
a plurality of nanowire phototransistors extending from the substrate, wherein individual nanowire phototransistors of the plurality of nanowire phototransistors comprise an emitter, a multi-quantum well, and a collector, wherein the emitter of individual nanowire phototransistors of the plurality of nanowire phototransistors are electrically coupled to the first electrode, wherein the collector of individual nanowire phototransistors of the plurality of nanowire phototransistors are electrically coupled to the second electrode.

2. The apparatus of claim 1, the integrated circuit die further comprising a photodetector array, the photodetector array comprising a plurality of pixels, wherein individual pixels of the plurality of pixels comprise a plurality of nanowire phototransistors, wherein the plurality of nanowire phototransistors of individual pixels of the plurality of pixels share a common emitter electrode and a common collector electrode.

3. The apparatus of claim 1, wherein the plurality of nanowire phototransistors form a photonic crystal.

4. The apparatus of claim 3, wherein the photonic crystal establishes an acceptance angle for the plurality of nanowire phototransistors.

5. The apparatus of claim 1, further comprising a multi-mode fiber, wherein an output of the multi-mode fiber is coupled to the plurality of nanowire phototransistors, wherein a plurality of micro-LEDs at a plurality of wavelengths are coupled to an input of the multi-mode fiber.

6. The apparatus of claim 1, further comprising one or more optical filters to filter one or more wavelengths of light from the plurality of nanowire phototransistors, wherein the one or more optical filters comprise a metasurface nanostructure.

7. The apparatus of claim 1, wherein, for individual nanowire phototransistors of the plurality of nanowire phototransistors, the emitter comprises gallium and nitrogen, the multi-quantum well comprises indium, gallium, and nitrogen, a collector comprises gallium and nitrogen, and a base comprises indium gallium and nitrogen.

8. The apparatus of claim 1, wherein, for individual nanowire phototransistors of the plurality of nanowire phototransistors, the emitter comprises silicon, the multi-quantum well comprises silicon and germanium, a collector comprises silicon, and a base comprises silicon and germanium.

9. The apparatus of claim 1, further comprising a network switch, the network switch comprising a circuit board, wherein the integrated circuit die is mounted on the circuit board.

10. An apparatus comprising:
an integrated circuit die, the integrated circuit die comprising a substrate; and
a plurality of photodetectors extending from the substrate,
further comprising, for individual photodetectors of the plurality of photodetectors, a first metasurface nanostructure above the photodetector and a second metasurface nanostructure below the photodetector, wherein, for individual photodetectors of the plurality of photodetectors, the first metasurface nanostructure and the second metasurface nanostructure form a resonant cavity that at least partially overlaps with the photodetector.

11. The apparatus of claim 10, wherein, for individual photodetectors of the plurality of photodetectors, the resonant cavity increases a detection efficiency of the photodetector by at least a factor of 1.5.

12. The apparatus of claim 10, wherein, for individual photodetectors of the plurality of photodetectors, the resonant cavity rejects one or more wavelengths outside of a target wavelength band.

13. The apparatus of claim 10, wherein, for individual photodetectors of the plurality of photodetectors, the first metasurface nanostructure establishes an acceptance angle for the photodetector.

14. The apparatus of claim 10, wherein, for individual photodetectors of the plurality of photodetectors, the first metasurface nanostructure has a length and width of at least 2 micrometers and comprises a two-dimensional array of nanoresonators, the two-dimensional array of nanoresonators having a pitch between 30-300 nanometers.

15. The apparatus of claim 10, wherein the plurality of photodetectors comprise a plurality of photodiodes.

16. The apparatus of claim 15, wherein individual photodiodes of the plurality of photodetectors comprise a p-doped region, an intrinsic region, and an n-doped region, the intrinsic region comprising a multi-quantum well.

17. The apparatus of claim 10, further comprising a circuit board, wherein the integrated circuit die is mounted on the circuit board.

18. A method comprising:
forming a release layer on a substrate;
creating a plurality of nanowire phototransistors on the release layer;
attaching a second substrate to the plurality of nanowire phototransistors; and
releasing the release layer.

19. The method of claim 18, the second substrate further comprising a photodetector array, the photodetector array comprising a plurality of pixels, wherein individual pixels of the plurality of pixels comprise a plurality of nanowire phototransistors, wherein the plurality of nanowire phototransistors of individual pixels of the plurality of pixels share a common emitter electrode and a common collector electrode.

20. The method of claim 18, further comprising forming one or more optical filters to filter one or more wavelengths of light from the plurality of nanowire phototransistors.
